(19) United States
(12) Patent Application Publication
(10) Pub. No.: US 2026/0026162 A1
(43) Pub. Date: Jan. 22, 2026

(54) DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Fei FANG, Beijing (CN); Ling SHI, Beijing (CN); Yipeng CHEN, Beijing (CN); Yuxiao LI, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/996,760

(22) PCT Filed: Apr. 17, 2024
(86) PCT No.: PCT/CN2024/088164

§ 371 Date: Jan. 17, 2025

(30) Foreign Application Priority Data
May 30, 2023 (CN) 202310627409.5

(51) Int. Cl. H10H 29/49; H01L 25/16; H10H 29/32; H10H 29/80

(52) U.S. Cl. CPC H10H 29/49; H01L 25/167; H10H 29/32; H10H 29/8321

(57) ABSTRACT

A display substrate and a display device are provided. The display substrate includes a base substrate, and a plurality of subpixels and a plurality of data lines arranged on the base substrate. Each of the subpixels includes a subpixel driving circuit and a light-emitting element coupled to each other. A plurality of subpixel driving circuits included in the plurality of subpixels includes a plurality of driving circuit columns, each of the driving circuit columns includes a plurality of subpixel driving circuits arranged in a first direction, light-emitting elements coupled to the subpixel driving circuits in a same driving circuit column emit light in a same color, and each of the data lines is coupled to the subpixel driving circuits in a corresponding driving circuit column.

### CROSS-REFERENCE TO RELATED APPLICATION

This application claims a priority of the Chinese patent application No. 202310627409.5 filed on May 30, 2023, which is incorporated herein by reference in its entirety.

### TECHNICAL FIELD

The present disclosure relates to the field of display technology, in particular to a display substrate and a display device.

### BACKGROUND

Along with the continuous development of the display technology, display products have been applied more and more widely, and the requirement on display quality of the display products becomes higher and higher. In order to achieve high-quality display, a resolution of the display product becomes higher and higher, leading to higher and higher power consumption of the display product. Hence, there is an urgent need to provide a scheme about how to reduce the power consumption of the display product.

### SUMMARY

An object of the present disclosure is to provide a display substrate and a display device, so as to solve the above-mentioned problem.

In order to achieve the above object, the present disclosure provides the following technical solutions.

In one aspect, the present disclosure provides in some embodiments a display substrate, including a base substrate, and a plurality of subpixels and a plurality of data lines arranged on the base substrate, each of the subpixels including a subpixel driving circuit and a light-emitting element coupled to each other. A plurality of subpixel driving circuits included in the plurality of subpixels includes a plurality of driving circuit columns, each of the driving circuit columns includes a plurality of subpixel driving circuits arranged in a first direction, light-emitting elements coupled to the subpixel driving circuits in a same driving circuit column emit light in a same color, and each of the data lines is coupled to the subpixel driving circuits in a corresponding driving circuit column. The plurality of driving circuit columns includes a plurality of first driving circuit columns and a plurality of second driving circuit columns, the plurality of first driving circuit columns and the plurality of second driving circuit columns are arranged alternately in a second direction, and the second direction intersects the first direction. The light-emitting elements coupled to the first driving circuit column are arranged in the first direction to form a first light-emitting element column, odd-numbered light-emitting elements in the light-emitting elements coupled to the second diving circuit column and even-numbered light-emitting elements in the light-emitting elements coupled to an adjacent second driving circuit column are arranged alternately in the first direction to form a second light-emitting element column, the second light-emitting element columns and the first light-emitting element columns are arranged alternately in the second direction, and the light-emitting elements in the first light-emitting element column are at least partially staggered with the light-emitting elements in the second light-emitting element column in the first direction.

In a possible embodiment of the present disclosure, the plurality of subpixel driving circuits included in the plurality of subpixels includes a plurality of driving circuit rows, and each of the driving circuit rows includes a plurality of subpixel driving circuits arranged in the second direction. The light-emitting elements coupled to odd-numbered subpixel driving circuits in the driving circuit row are arranged in the second direction to form a first light-emitting element row, the light-emitting elements coupled to even-numbered subpixel driving circuits in the driving circuit row are arranged in the second direction to form a second light-emitting element row, the first light-emitting element rows and the second light-emitting element rows are arranged alternately in the first direction, and the light-emitting elements in the first light-emitting element row are at least partially staggered with the light-emitting elements in the second light-emitting element row in the second direction.

In a possible embodiment of the present disclosure, the first driving circuit column is coupled to first-color light-emitting elements, a first part of second driving circuit columns in the plurality of second driving circuit columns are coupled to second-color light-emitting elements, and a second part of second driving circuit columns in the plurality of second driving circuit columns are coupled to third-color light-emitting elements. The first light-emitting element column includes a plurality of first-color light-emitting elements arranged in the first direction, and the second light-emitting element column includes the second-color light-emitting elements and the third-color light-emitting elements arranged alternately in the first direction.

In a possible embodiment of the present disclosure, one of the first light-emitting element row and the second light-emitting element row includes a plurality of first-color light-emitting elements arranged in the second direction, and the other of the first light-emitting element row and the second light-emitting element row includes the second-color light-emitting elements and the third-color light-emitting elements arranged alternately in the second direction.

In a possible embodiment of the present disclosure, the light-emitting element includes an anode pattern, the anode pattern includes an anode body and an anode extension member coupled to each other, the subpixel further includes a conductive connection structure, and the subpixel driving circuit is coupled to the anode extension member via the conductive connection structure.

In a possible embodiment of the present disclosure, the conductive connection structure includes at least two conductive connection members, the at least two conductive connection members are laminated one on another in a direction away from the base substrate, the subpixel driving circuit includes a driving transistor and a light-emission control transistor, a first electrode of the light-emission control transistor is coupled to a second electrode of the driving transistor, and a second electrode of the light-emission control transistor is coupled to the anode extension member via the at least two conductive connection members.

In a possible embodiment of the present disclosure, the conductive connection structure includes a first conductive connection member, a second conductive connection member and a third conductive connection member laminated one on another in a direction away from the base substrate, the second conductive connection member is coupled to the first conductive connection member and the third conductive connection member, the first conductive connection member is coupled to the second electrode of the light-emission control transistor, and the third conductive connection member is coupled to the anode extension member. An orthogonal projection of the first conductive connection member onto the base substrate does not overlap with an orthogonal projection of the third conductive connection member onto the base substrate.

In a possible embodiment of the present disclosure, the display substrate further includes a first source/drain metal layer, a second source/drain metal layer and a third source/drain metal layer laminated one on another in a direction away from the base substrate. The first conductive connection member is arranged at a same layer, and made of a same material, as the first source/drain metal layer, the second conductive connection member is arranged at a same layer, and made of a same material, as the second source/drain metal layer, and the third conductive connection member is arranged at a same layer, and made of a same material, as the third source/drain metal layer.

In a possible embodiment of the present disclosure, the plurality of driving circuit columns includes a plurality of driving circuit groups arranged in the second direction, the driving circuit group includes a first driving circuit column and a second driving circuit column proximate to each other, the driving circuit group includes first driving units and second driving units arranged alternately in the first direction, the first driving unit includes a first subpixel driving circuit and a second subpixel driving circuit arranged sequentially in the second direction, and the second driving unit includes a third subpixel driving circuit and a fourth subpixel driving circuit arranged sequentially in the second direction. The first subpixel driving circuit is coupled to a first anode extension member via a first conductive connection structure, the second subpixel driving circuit is coupled to a second anode extension member via a second conductive connection structure, the third subpixel driving circuit is coupled to a third anode extension member via a third conductive connection structure, and the fourth subpixel driving circuit is coupled to a fourth anode extension member via a fourth conductive connection structure. An orthogonal projection of the first anode extension member onto the base substrate does not overlap with an orthogonal projection of the second conductive connection structure onto the base substrate, and/or an orthogonal projection of the third anode extension member onto the base substrate does not overlap with an orthogonal projection of the fourth conductive connection structure onto the base substrate.

In a possible embodiment of the present disclosure, the orthogonal projection of the first anode extension member onto the base substrate does not overlap with the orthogonal projection of the first conductive connection member in the first conductive connection structure onto the base substrate, and/or the orthogonal projection of the first anode extension member onto the base substrate does not overlap with an orthogonal projection of the second conductive connection member in the first conductive connection structure onto the base substrate.

In a possible embodiment of the present disclosure, the orthogonal projection of the third anode extension member onto the base substrate does not overlap with the orthogonal projection of the first conductive connection member in the third conductive connection structure onto the base substrate, and/or the orthogonal projection of the third anode extension member onto the base substrate does not overlap with an orthogonal projection of the second conductive connection member in the third conductive connection structure onto the base substrate.

In a possible embodiment of the present disclosure, an orthogonal projection of the second anode extension member onto the base substrate at least partially overlaps with an orthogonal projection of the first conductive connection structure onto the base substrate.

In a possible embodiment of the present disclosure, the orthogonal projection of the second anode extension member onto the base substrate at least partially overlaps with the orthogonal projection of the second conductive connection member in the first conductive connection structure onto the base substrate, and/or the orthogonal projection of the second anode extension member onto the base substrate at least partially overlaps with the orthogonal projection of the third conductive connection member in the first conductive connection structure onto the base substrate.

In a possible embodiment of the present disclosure, the orthogonal projection of the second anode extension member onto the base substrate does not overlap with the orthogonal projection the first conductive connection member in the second conductive connection structure onto the base substrate, and/or the orthogonal projection of the second anode extension member onto the base substrate at least partially overlaps with the orthogonal projection the second conductive connection member in the second conductive connection structure onto the base substrate.

In a possible embodiment of the present disclosure, the second conductive connection member in the first conductive connection structure is arranged symmetrical with the second conductive connection member in the second conductive connection structure, and/or the second conductive connection member in the third conductive connection structure is arranged symmetrical with the second conductive connection member in the fourth conductive connection structure.

In a possible embodiment of the present disclosure, an orthogonal projection of the second anode extension member onto the base substrate does not overlap with an orthogonal projection of the first conductive connection structure onto the base substrate.

In a possible embodiment of the present disclosure, an orthogonal projection of a second anode body coupled to the second anode extension member onto the base substrate at least partially overlaps with the orthogonal projection of the first conductive connection member in an adjacent second conductive connection structure onto the base substrate, and/or the orthogonal projection of the second anode body coupled to the second anode extension member onto the base substrate at least partially overlaps with the orthogonal projection of the second conductive connection member in the adjacent second conductive connection structure onto the base substrate. The adjacent second conductive connection structure and the second conductive connection structure coupled to the second anode extension member are arranged in the second direction.

In a possible embodiment of the present disclosure, the orthogonal projection of the third conductive connection member in the second conductive connection structure onto the base substrate at least partially overlaps with the orthogonal projection of the second conductive connection member in the first conductive connection structure onto the base substrate; and/or the orthogonal projection of the second conductive connection member in the second conductive connection structure onto the base substrate does not overlap with the orthogonal projection of the third conductive connection member in the first conductive connection structure onto the base substrate.

In a possible embodiment of the present disclosure, at least a portion of the third conductive connection member in the first conductive connection structure extends in the first direction, at least a portion of the second conductive connection member in the second conductive connection structure extends in the second direction, and the orthogonal projection of the third conductive connection member in the first conductive connection structure onto the base substrate and the orthogonal projection of the second conductive connection member in the second conductive connection structure onto the base substrate are arranged in the first direction.

In a possible embodiment of the present disclosure, at least a portion of the third conductive connection member in the first conductive connection structure extends in a third direction, the third direction intersects the first direction and the second direction, and one end of the third conductive connection member in the first conductive connection structure is at least partially surrounded by the third conductive connection member in the second conductive connection structure.

In a possible embodiment of the present disclosure, an orthogonal projection of the fourth anode extension member onto the base substrate does not overlap with the orthogonal projection of the third conductive connection structure onto the base substrate.

In a possible embodiment of the present disclosure, the orthogonal projection of the fourth anode extension member onto the base substrate does not overlap with the orthogonal projection of the first conductive connection member in the fourth conductive connection structure onto the base substrate, and/or the orthogonal projection of the fourth anode extension member onto the base substrate does not overlap with the orthogonal projection of the second conductive connection member in the fourth conductive connection structure onto the base substrate.

In a possible embodiment of the present disclosure, the fourth anode extension member includes at least a portion extending in the second direction, the second conductive connection member in the fourth conductive connection structure includes at least a portion extending in the second direction, and the orthogonal projection of the fourth anode extension member onto the base substrate and the orthogonal projection of the second conductive connection member in the fourth conductive connection structure onto the base substrate are arranged in the first direction.

In a possible embodiment of the present disclosure, the third conductive connection member in the fourth conductive connection structure includes at least a portion extending the first direction, the second conductive connection member in the fourth conductive connection structure includes a first sub-portion and a second sub-portion coupled to each other, the first sub-portion extends in the second direction, an extension direction of the second sub-portion intersects the first direction, the first sub-portion is coupled to the first conductive connection member, and the second sub-portion is coupled to the third conductive connection member.

In a possible embodiment of the present disclosure, the first sub-portion and the second conductive connection member in the first conductive connection structure are arranged in the second direction, and the second sub-portion is at least partially staggered with the second conductive connection member in the first conductive connection structure in the first direction.

In a possible embodiment of the present disclosure, an extension direction of the third conductive connection member in the first conductive connection structure intersects the first direction, the second conductive connection member in the first conductive connection structure includes a third sub-portion and a fourth sub-portion coupled to each other, the third sub-portion is coupled to the first conductive connection member, the fourth sub-portion is coupled to the third conductive connection member, the third sub-portion extends in the second direction, an extension direction of the fourth sub-portion intersects an extension direction of the third sub-portion, the third sub-portion and the first sub-portion are arranged in the second direction, and the fourth sub-portion and the second sub-portion are arranged in the second direction.

In a possible embodiment of the present disclosure, the second conductive connection member in the first conductive connection structure and the second conductive connection member in the third conductive connection structure extend in a same direction; the second conductive connection member in the second conductive connection structure and the second conductive connection member in the fourth conductive connection structure extend in a same direction; and in the first conductive connection structure, the second conductive connection member has a first extension direction from the first conductive connection member to the third conductive connection member, in the second conductive connection structure, the second conductive connection member has a second extension direction from the first conductive connection member to the third conductive connection member, and the second extension direction is at least partially opposite to the first extension direction.

In another aspect, the present disclosure provides in some embodiments a display substrate, including a base substrate, and a plurality of subpixels and a plurality of data lines arranged on the base substrate, each of the subpixels including a subpixel driving circuit and a light-emitting element coupled to each other. A plurality of subpixel driving circuits included in the plurality of subpixels includes a plurality of driving circuit columns, each of the driving circuit columns includes a plurality of subpixel driving circuits arranged in a first direction, light-emitting elements coupled to the subpixel driving circuits in a same driving circuit column emit light in a same color, and each of the data lines is coupled to the subpixel driving circuits in a corresponding driving circuit column. The plurality of driving circuit columns includes a plurality of first driving circuit columns and a plurality of second driving circuit columns, the plurality of first driving circuit columns and the plurality of second driving circuit columns are arranged alternately in a second direction, and the second direction intersects the first direction. The light-emitting elements coupled to the first driving circuit column are arranged in the first direction to form a first light-emitting element column, and the light-emitting elements coupled to the second diving circuit column are arranged in the first direction to form a second light-emitting element column. A driving transistor in the subpixel driving circuit includes an active pattern, the light-emitting element includes an anode pattern, the anode pattern includes an anode body and an anode extension member coupled to each other, and in a same light-emitting element column, an orthogonal projection of the anode body onto the base substrate does not overlap with an orthogonal projection of the active pattern of the driving transistor in the subpixel driving circuit coupled to the anode body onto the base substrate.

In a possible embodiment of the present disclosure, an orthogonal projection of the first light-emitting element column onto the base substrate at least partially overlaps with an orthogonal projection of the second driving circuit column onto the base substrate, and an orthogonal projection of the second light-emitting element column onto the base substrate at least partially overlaps with an orthogonal projection of the first driving circuit column onto the base substrate.

In yet another aspect, the present disclosure provides in some embodiments a display device including the above-mentioned display substrate.

### BRIEF DESCRIPTION OF THE DRAWINGS

The following drawings are provided to facilitate the understanding of the present disclosure, and constitute a portion of the description. These drawings and the following embodiments are for illustrative purposes only, but shall not be construed as limiting the present disclosure. In these drawings,

FIG. 1 is a circuit diagram of a subpixel driving circuit according to one embodiment of the present disclosure;

FIG. 2 is a sectional view of film layers of a display substrate according to one embodiment of the present disclosure;

FIG. 3 is a schematic view showing the layout of subpixel driving circuits and light-emitting elements of subpixels in the display substrate according to one embodiment of the present disclosure;

FIG. 4 is a schematic view showing the layout of the subpixel driving circuits in FIG. 3;

FIG. 5 is a schematic view showing the layout of a light-shielding layer in the display substrate according to one embodiment of the present disclosure;

FIG. 6 is a schematic view showing the layout of the light-shielding layer and a first active layer in the display substrate according to one embodiment of the present disclosure;

FIG. 7 is a schematic view showing the layout of the first active layer and a first gate metal layer in the display substrate according to one embodiment of the present disclosure;

FIG. 8 is a schematic view showing the layout of a second gate metal layer added on the basis of FIG. 7;

FIG. 9 is a schematic view showing the layout of a third gate metal layer added on the basis of FIG. 8;

FIG. 10 is a schematic view showing the layout of a second active layer added on the basis of FIG. 9;

FIG. 11 is a schematic view showing the layout of via-holes in an interlayer insulation layer added on the basis of FIG. 8;

FIG. 12 is a schematic view showing the layout of two subpixel driving circuits in FIG. 11;

FIG. 13 is a schematic view showing the layout of the second active layer and the third gate metal layer in the display substrate according to one embodiment of the present disclosure;

FIG. 14 is a schematic view showing the layout of a first source/drain metal layer added on the basis of FIG. 13;

FIG. 15 is a schematic view showing via-holes in the interlayer insulation layer and the first source/drain metal layer according to one embodiment of the present disclosure;

FIG. 16 is a schematic view showing via-holes in a passivation layer and the source/drain metal layer and via-holes in a first planarization layer according to one embodiment of the present disclosure;

FIG. 17 is a schematic view showing the layout of the first source/drain metal layer added on the basis of FIG. 11;

FIG. 18 is a schematic view showing the layout of the second active layer and the third gate metal layer added on the basis of FIG. 17;

FIG. 19 is a schematic view showing the layout of the first source/drain metal layer and the second source/drain metal layer in the display substrate according to one embodiment of the present disclosure;

FIG. 20 is a schematic view showing the layout of the second source/drain metal layer in FIG. 19;

FIG. 21 is a schematic view showing the layout of the second source/drain metal layer and a third source/drain metal layer in the display substrate according to one embodiment of the present disclosure;

FIG. 22 is a schematic view showing the layout of the third source/drain metal layer in FIG. 21;

FIG. 23 is a schematic view showing the layout of the third source/drain metal layer and an anode layer in the display substrate according to one embodiment of the present disclosure;

FIG. 24 is a schematic view showing the layout of the anode layer added on the basis of FIG. 21;

FIG. 25 is another schematic view showing the layout of the first source/drain metal layer and the second source/drain metal layer in the display substrate according to one embodiment of the present disclosure;

FIG. 26 is a schematic view showing the layout of the second source/drain metal layer in FIG. 25;

FIG. 27 is another schematic view showing the second source/drain metal layer and the third source/drain metal layer in the display substrate according to one embodiment of the present disclosure;

FIG. 28 is a schematic view showing the layout of the third source/drain metal layer in FIG. 27;

FIG. 29 is another schematic view showing the layout of the third source/drain metal layer and the anode layer in the display substrate according to one embodiment of the present disclosure;

FIG. 30 is another schematic view showing the layout of the anode layer added on the basis of FIG. 27;

FIG. 31 is yet another schematic view showing the layout of the first source/drain metal layer and the second source/drain metal layer in the display substrate according to one embodiment of the present disclosure;

FIG. 32 is a schematic view showing the layout of the second source/drain metal layer in FIG. 31;

FIG. 33 is yet another schematic view showing the layout of the second source/drain metal layer and the third source/drain metal layer in the display substrate according to one embodiment of the present disclosure;

FIG. 34 is a schematic view showing the layout of the third source/drain metal layer in FIG. 33;

FIG. 35 is yet another schematic view showing the third source/drain metal layer and the anode layer in the display substrate according to one embodiment of the present disclosure; and

FIG. 36 is yet another schematic view showing the anode layer added on the basis of FIG. 33.

### DETAILED DESCRIPTION OF THE EMBODIMENTS

The present disclosure will be described hereinafter in conjunction with the drawings and embodiments.

It is found through researches that, in the related art, in a plurality of columns of subpixels included in a display product, there is a difference in colors of the subpixels in a same column. Data signals are written into the subpixels in a same column via a same data line, and the data signals required by the subpixels in different colors are different from each other. Hence, in a case that the subpixels are scanned by a shift register unit row by row, i.e., in a case that the data signals are applied by the data line to the subpixels in a same column sequentially, a driving chip needs to charge the data signals repeatedly in a jumping manner, so that the data line provides the data signals to the subpixels in different colors within respective ranges. However, in this mode, the power consumption of the driving chip increases, and thereby the overall power consumption of the display product increases.

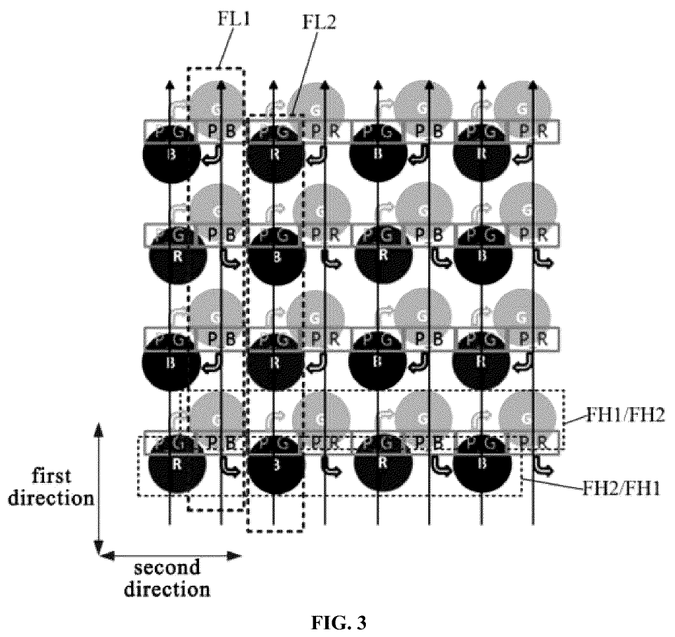

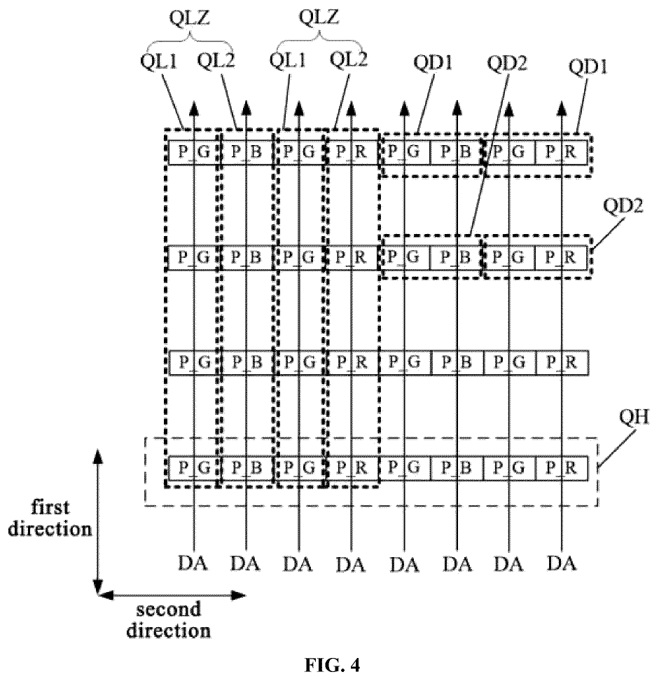

Referring to FIGS. 3 and 4, the present disclosure provides in some embodiments a display substrate, which includes a base substrate, and a plurality of subpixels and a plurality of data lines DA arranged on the base substrate. The subpixel includes a subpixel driving circuit (e.g., a red subpixel driving circuit P_R, a green subpixel driving circuit P_G or a blue subpixel driving circuit P_B) and a light-emitting element (e.g., a red light-emitting element R, a green light-emitting element G or a blue light-emitting element B) coupled to each other.

A plurality of subpixel driving circuits included in the plurality of subpixels includes a plurality of driving circuit columns (e.g., a first driving circuit column QL1 and a second driving circuit column QL2), the driving circuit column includes a plurality of subpixel driving circuits arranged in a first direction, light-emitting elements coupled to the subpixel driving circuits in a same driving circuit column emit light in a same color, and the data line DA is coupled to the subpixel driving circuits in a corresponding driving circuit column.

The plurality of driving circuit columns includes a plurality of first driving circuit columns QL1 and a plurality of second driving circuit columns QL2, the plurality of first driving circuit columns QL1 and the plurality of second driving circuit columns QL2 are arranged alternately in a second direction, and the second direction intersects the first direction.

The light-emitting elements coupled to the first driving circuit column QL1 are arranged in the first direction to form a first light-emitting element column FL1, odd-numbered light-emitting elements in the light-emitting elements coupled to the second diving circuit column QL2 and even-numbered light-emitting elements in the light-emitting elements coupled to an adjacent second driving circuit column QL2 are arranged alternately in the first direction to form a second light-emitting element column FL2, the second light-emitting element columns FL2 and the first light-emitting element columns FL1 are arranged alternately in the second direction, and the light-emitting elements in the first light-emitting element column FL1 are at least partially staggered with the light-emitting elements in the second light-emitting element column FL2 in the first direction. For example, in FIG. 3, the red light-emitting elements R are staggered with the green light-emitting elements G, and the blue light-emitting elements B are staggered with the green light-emitting elements G.

For example, the display substrate includes a plurality of subpixels, and a plurality of subpixel driving circuits in the plurality of subpixels is arranged in an array form. The plurality of subpixel driving circuits includes a plurality of driving circuit rows QH and a plurality of driving circuit columns. The plurality of driving circuit rows QH is arranged in the first direction, and the driving circuit row QH includes a plurality of subpixel driving circuits arranged in the second direction. The plurality of driving circuit columns is arranged in the second direction, and the driving circuit column includes a plurality of subpixel driving circuits arranged in the first direction. For example, the first direction intersects the second direction. For example, the first direction includes a longitudinal direction, and the second direction includes a transverse direction.

For example, the subpixel includes a subpixel driving circuit and a light-emitting element. The subpixel driving circuit is coupled to an anode of the light-emitting element, and configured to provide a driving signal to the light-emitting signal, so as to drive the light-emitting element to emit light.

For example, the display substrate includes a plurality of data lines DA corresponding to the plurality of driving circuit columns respectively. The data line DA is coupled to the subpixel driving circuits in a corresponding driving circuit column.

For example, the plurality of driving circuit columns includes a plurality of first driving circuit columns QL1 and a plurality of second driving circuit columns QL2. The plurality of first driving circuit columns QL1 and the plurality of second driving circuit columns QL2 are arranged alternately in the second direction, and the light-emitting elements coupled to the first driving circuit column QL1 have a color different from the light-emitting elements coupled to the second driving circuit column QL2. For example, the first driving circuit columns QL1 are coupled to the green light-emitting elements G, a first part of the plurality of second driving circuit columns QL2 are coupled to the red light-emitting elements R, and a second part of the plurality of second driving circuit columns QL2 are coupled to the blue light-emitting elements B. However, the present disclosure is not limited thereto.

For example, the light-emitting elements coupled to the first driving circuit column QL1 are arranged in the first direction to form a first light-emitting element column FL1. All the light-emitting elements in the plurality of first light-emitting element columns FL1 include a plurality of plurality of light-emitting element rows, and the light-emitting element row includes a plurality of light-emitting elements arranged in the second direction and having a same color, e.g., the green light-emitting elements. However, the present disclosure is not limited thereto.

For example, in every two adjacent second driving circuit columns QL2, odd-numbered light-emitting elements in the light-emitting elements coupled to one of the second driving circuit columns QL2 and even-numbered light-emitting elements in the light-emitting elements coupled to the other of the second driving circuit columns QL2 are arranged alternately in the first direction to form a second light-emitting element column FL2. All the light-emitting elements in the plurality of second light-emitting element columns FL2 include a plurality of light-emitting rows, and the light-emitting element row includes a plurality of light-emitting elements which are arranged in the second direction and whose colors change alternately, e.g., the red light-emitting elements and the blue light-emitting elements. However, the present disclosure is not limited thereto.

For example, the second light-emitting element columns FL2 and the first light-emitting element columns FL1 are arranged alternately in the second direction, and the light-emitting elements in the first light-emitting element column FL1 are at least partially staggered with the light-emitting elements in the second light-emitting element column FL2 in the first direction. The light-emitting element rows formed by the light-emitting elements in the plurality of first light-emitting element columns FL1 and the light-emitting element rows formed by the light-emitting elements in the plurality of second light-emitting element columns FL2 are arranged alternately in the first direction.

For example, in a case that the subpixels are arranged in the above-mentioned mode, two adjacent green light-emitting elements, one red light-emitting element and one blue light-emitting element together form a light-emitting element repeat unit, and the light-emitting element repeat unit is in a diamond-like arrangement mode.

Based on the above-mentioned specific structure of the display substrate, in the embodiments of the present disclosure, the light-emitting elements in the plurality of subpixels form the light-emitting element repeat units each in the diamond-like arrangement mode. In addition, the plurality of subpixel driving circuits in the plurality of subpixels includes the plurality of driving circuit columns, the driving circuit column includes a plurality of subpixel driving circuits arranged in the first direction, the light-emitting elements coupled to the subpixel driving circuits in a same driving circuit column emit light in a same color, and the data line DA is coupled to the subpixel driving circuits in a corresponding driving circuit column. The light-emitting elements coupled to the subpixel driving circuits in a driving circuit column coupled to the data line DA emit light in a same color, so in a case that the subpixels are scanned by a shift register unit row by row, i.e., in a case that the data line DA provides data signals to the subpixels in one column sequentially, a voltage of the data signal transmitted via the data line DA changes within a very tiny range or does not change. In this way, a driving chip does not need to charge the data signal repeatedly in a jumping manner, and the data line DA provides the data signal within a corresponding range to the subpixels coupled to the data line DA, so as to effectively reduce the power consumption of the driving chip, thereby to reduce the overall power consumption of the display product.

Hence, in the display substrate according to the embodiments of the present disclosure, in a case of the diamond-like arrangement mode, it is able to reduce the power consumption of the driving chip, thereby to reduce the overall power consumption of the display product.

As shown in FIGS. 3 and 4, in some embodiments of the present disclosure, the plurality of subpixel driving circuits in the plurality of subpixels includes a plurality of driving circuit rows QH, and the driving circuit row QH includes a plurality of subpixel driving circuits arranged in the second direction.

The light-emitting elements coupled to odd-numbered subpixel driving circuits in the driving circuit row QH are arranged in the second direction to form the first light-emitting element row FH1. The light-emitting elements coupled to even-numbered subpixel driving circuits in the driving circuity row QH are arranged in the second direction to form the second light-emitting element row FH2. In the first direction, the first light-emitting element rows FH1 and the second light-emitting element rows FH2 are arranged alternately. The light-emitting elements in the first light-emitting element row FH1 are at least partially staggered with the light-emitting elements in the second light-emitting element row FH2.

For example, the first light-emitting element row FH1 merely includes green light-emitting elements G, and the second light-emitting element row FH2 includes red light-emitting elements R and blue light-emitting elements B arranged alternately in the second direction. Alternatively, the first light-emitting element row FH1 includes red light-emitting elements R and blue light-emitting elements arranged alternately in the second direction, and the second light-emitting element row FH2 merely includes green light-emitting elements G.

For example, the light-emitting elements in the first light-emitting element row FH1 are at least partially staggered with the light-emitting elements in the second light-emitting element row FH2, and the light-emitting elements in the first light-emitting element row FH1 are at least partially staggered with the light-emitting elements in the second light-emitting element row FH2.

In the display substrate provided in the above embodiments of the present disclosure, in a case that the diamond-like arrangement mode is achieved as mentioned hereinabove, it is able to reduce the power consumption of the driving chip, thereby to reduce the overall power consumption of the display product.

As shown in FIGS. 3 and 4, in some embodiments of the present disclosure, the first driving circuit columns QL1 are coupled to first-color light-emitting elements, a first part of the plurality of second driving circuit columns QL2 are coupled to second-color light-emitting elements, and a second part of the second driving circuit columns QL2 are coupled to the third-color light-emitting elements.

The first light-emitting element column FL1 includes a plurality of first-color light-emitting elements arranged in the first direction, and the second light-emitting element column FL2 includes a plurality of second-color light-emitting elements and a plurality of third-color light-emitting elements arranged alternately in the first direction.

For example, the first-color light-emitting element includes a green light-emitting element G, the second-color light-emitting element includes a red light-emitting element R, and the third-color light-emitting element includes a blue light-emitting element B. However, the present disclosure is not limited thereto.

For example, in two adjacent second light-emitting element columns FL2, odd-numbered light-emitting elements in one of the two second light-emitting element columns FL2 are the second-color light-emitting elements, and even-numbered light-emitting elements are the third-color light-emitting elements. Even-numbered light-emitting elements in the other of the two second light-emitting element columns FL2 are the second-color light-emitting elements, and odd-numbered light-emitting elements are the third-color light-emitting elements. Four light-emitting element columns arranged sequentially in the second direction, i.e., one first light-emitting element column FL1, one second light-emitting element column FL2, one first light-emitting element column FL1 and one second light-emitting element column FL2, form a column repeat unit, and the display substrate includes a plurality of column repeat units.

In the display substrate provided in the embodiments of the present disclosure, in a case that the diamond-like arrangement mode is achieved as mentioned hereinabove, it is able to reduce the power consumption of the driving chip, thereby to reduce the overall power consumption of the display product.

As shown in FIGS. 3 and 4, in some embodiments of the present disclosure, one of the first light-emitting element row FH1 and the second light-emitting element row FH2 includes a plurality of first-color light-emitting elements arranged in the second direction, and the other of the first light-emitting element row FH1 and the second light-emitting element row FH2 includes a plurality of second-color light-emitting elements and a plurality of third-color light-emitting elements arranged alternately in the second direction.

In a case that the first light-emitting element row FH1 includes a plurality of first-color light-emitting elements arranged in the second direction and the second light-emitting element row FH2 includes a plurality of second-color light-emitting elements and a plurality of third-color light-emitting elements arranged alternately in the second direction, for example, in two adjacent second light-emitting element rows FH2, odd-numbered light-emitting elements in one of the two second light-emitting element rows FH2 are the second-color light-emitting elements, and even-numbered light-emitting elements are the third-color light-emitting elements. In the other of the two second light-emitting element rows FH2, even-numbered light-emitting elements are the second-color light-emitting elements, and odd-numbered light-emitting elements are the third-color light-emitting elements. Four light-emitting element rows arranged sequentially in the first direction, i.e., one first light-emitting element row FH1, one second light-emitting element row FH2, one first light-emitting element row FH1 and one second light-emitting element row FH2, form a row repeat unit, and the display substrate includes a plurality of row repeat units.

In the display substrate provided in the embodiments of the present disclosure, in a case that the diamond-like arrangement mode is achieved as mentioned hereinabove, it is able to reduce the power consumption of the driving chip, thereby to reduce the overall power consumption of the display product.

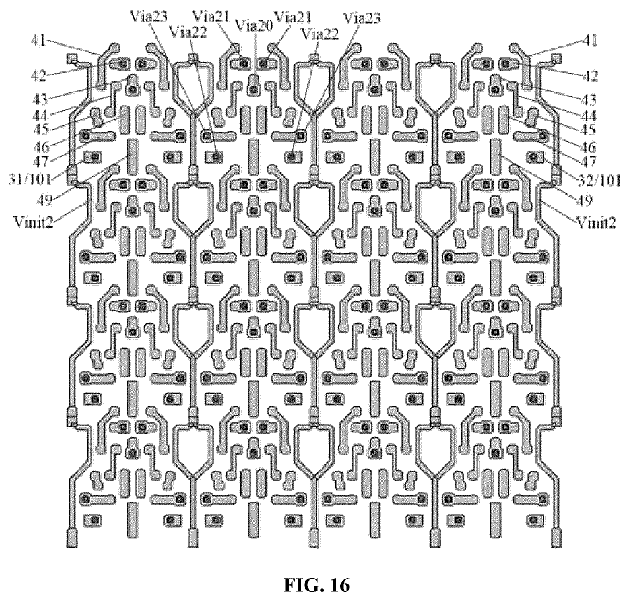

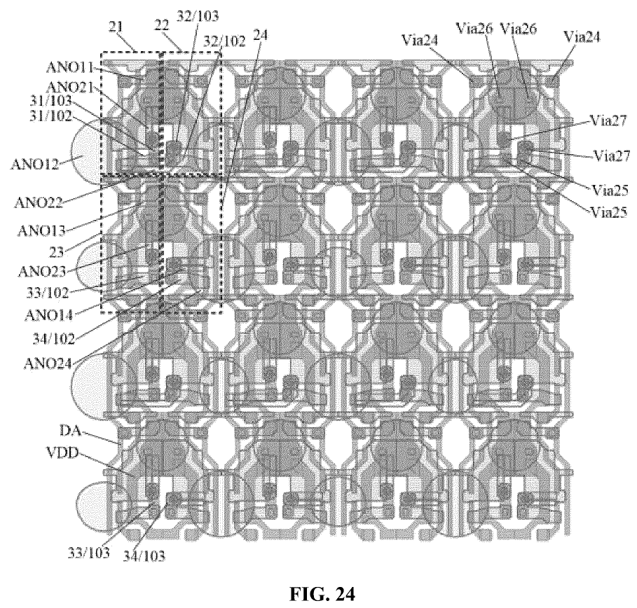

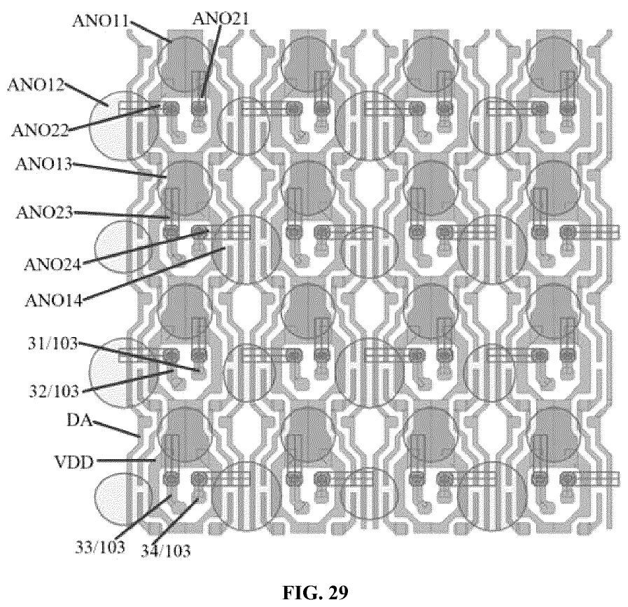

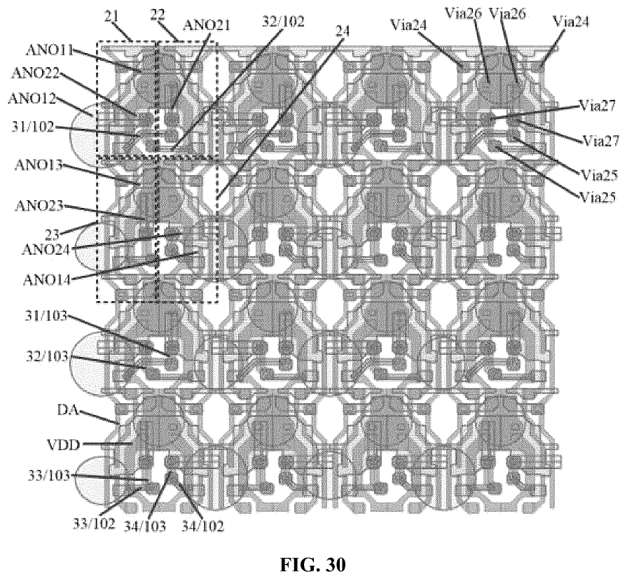

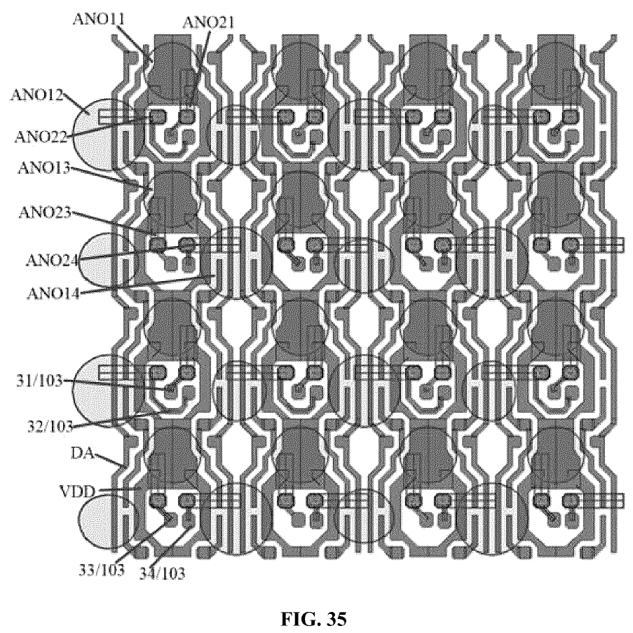

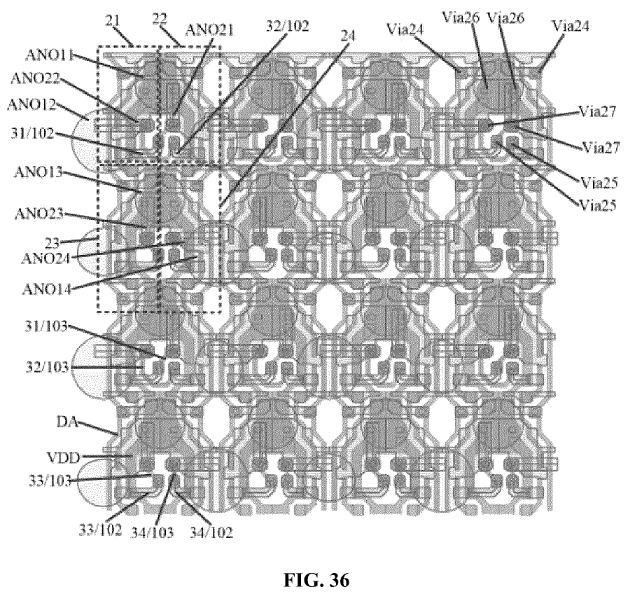

As shown in FIGS. 16, 19, 23, 24, 29, 30, 35 and 36, in some embodiments of the present disclosure, the light-emitting element includes an anode pattern, and the anode pattern includes an anode body (e.g., a first anode body ANO11, a second anode body ANO12, a third anode body ANO13 and a fourth anode body ANO14) and an anode extension member (e.g., a first anode extension member ANO21, a second anode extension member ANO22, a third anode extension member ANO23 and a fourth anode extension member ANO24) coupled to each other. The subpixel further includes a conductive connection structure (e.g., a first conductive connection structure 31, a second conductive connection structure 32, a third conductive connection structure 33 and a fourth conductive connection structure 34), and the subpixel driving circuit is coupled to the anode extension member via the conductive connection structure.

For example, the anode body and the anode extension member form an integral piece. At least a part of the anode body is located in a pixel aperture region of the subpixel. The anode extension member is located in a pixel non-aperture region of the subpixel.

For example, the anode body is, but not limited to, a circular, elliptical, hexagonal, quadrilateral or pentagonal shape.

It should be appreciated that, the light-emitting elements included in the above-mentioned light-emitting element row or light-emitting element column and arranged in the first direction or the second direction may refer to the anode bodies in the light-emitting elements, i.e., the anode bodies of the anode patterns in the light-emitting elements are arranged in the first direction or the second direction.

For example, the conductive connection structure may be of a single-layered structure, a double-layered structure or a multi-layered structure, depending on an actual situation.

For example, the conductive connection structure is located at a side of the subpixel driving circuit away from the base substrate, and the light-emitting element is located at a side of the conductive connection structure away from the base substrate.

For example, the light-emitting element further includes a light-emitting functional layer and a cathode layer. The light-emitting functional layer is arranged between the anode pattern and the cathode layer, and the cathode layer is arranged at a side of the anode pattern away from the base substrate.

In the display substrate provided in the embodiments of the present disclosure, the subpixel driving circuit is coupled to the anode extension member via the conductive connection structure, and the conductive connection structure and the anode extension member are provided with an appropriate structure and an appropriate layout, so as to achieve the diamond-like arrangement mode of the light-emitting elements, and enable the light-emitting elements coupled to the driving circuit column coupled to the data line DA to emit light in a same color.

As shown in FIGS. 16, 19, 23, 24, 29, 30, 35 and 36, in some embodiments of the present disclosure, the conductive connection structure includes at least two conductive connection members (e.g., a first conductive connection member 101, a second conductive connection member 102 and a third conductive connection member 103), and the at least two conductive connection members are laminated one on another in a direction away from the base substrate. The subpixel driving circuit includes a driving transistor (i.e., a third transistor T3) and a light-emission control transistor (i.e., a sixth transistor T6). A first electrode of the light-emission control transistor is coupled to a second electrode of the driving transistor, and a second electrode of the light-emission control transistor is coupled to the anode extension member via the at least two conductive connection members sequentially.

For example, the at least two conductive connection members are coupled to each other sequentially. The second electrode of the light-emission control transistor is coupled to a conductive connection member in the at least two conductive connection members closest to the base substrate, and a conductive connection member in the at least two conductive connection members furthest from the base substrate is coupled to the anode extension member.

The subpixel driving circuit may be of various circuit structures, including but not limited to a Low Temperature Poly-Silicon (LTPS) subpixel driving circuit or a Low Temperature Polycrystalline Oxide (LTPO) subpixel driving circuit. A specific circuit structure may include, but not limited to, a 7T1C (including 7 transistors and 1 capacitor) circuit structure, an 8T1C (including 8 transistors and 1 capacitor) circuit structure, or an 8T2C (including 8 transistors and 2 capacitors) circuit structure.

The following description will be given in a case that the subpixel driving circuit includes an LTPO subpixel driving circuit of an 8T2C circuit structure.

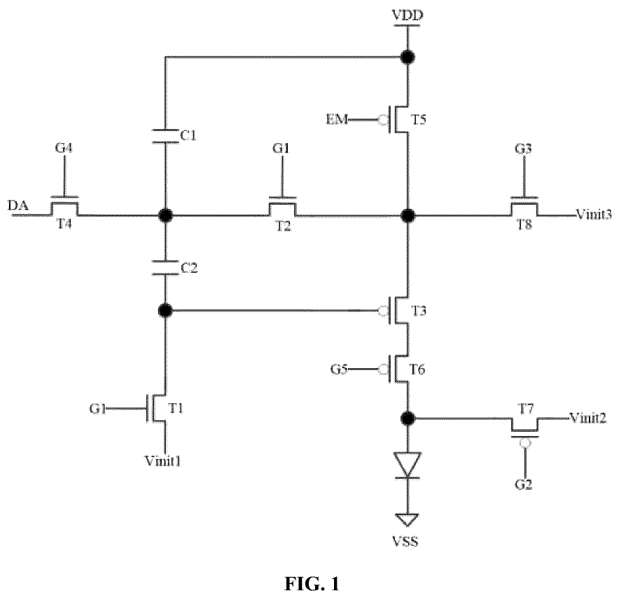

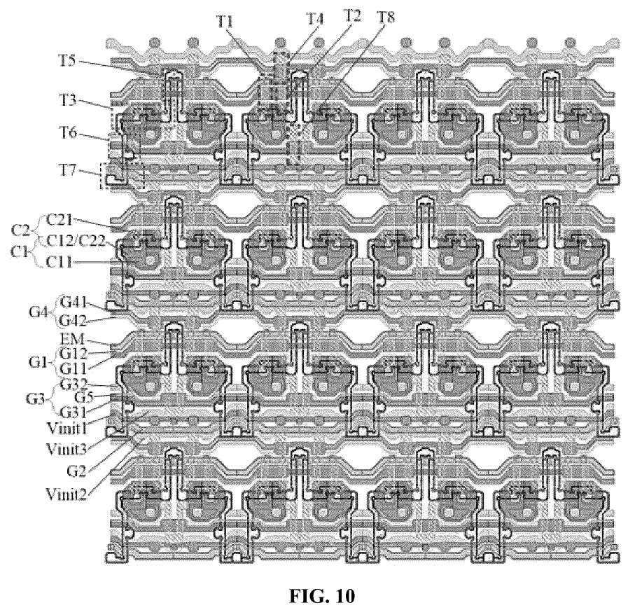

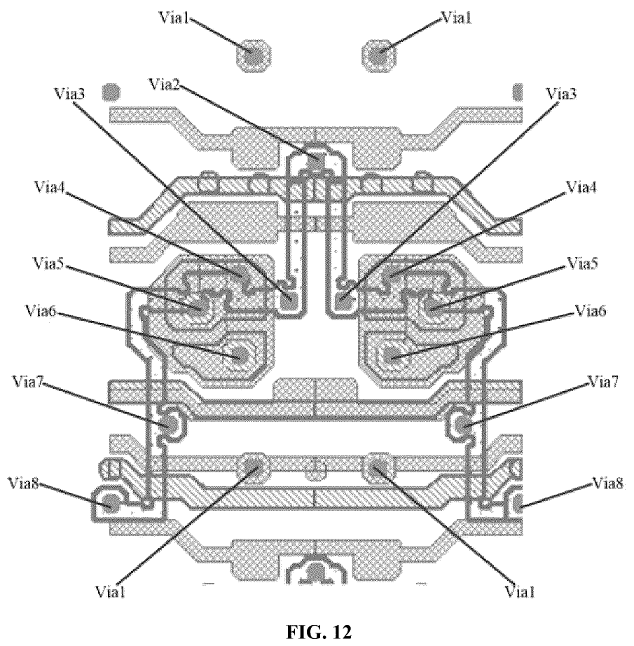

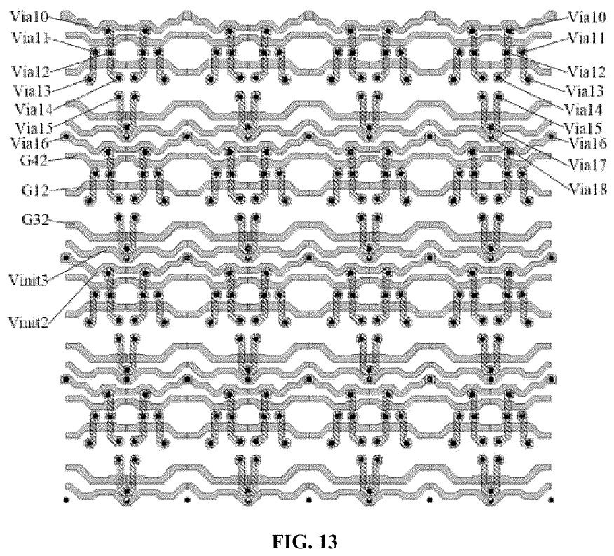

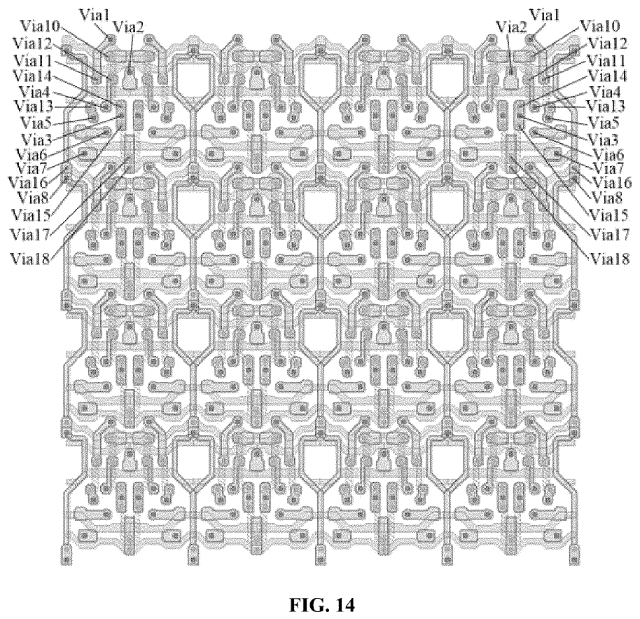

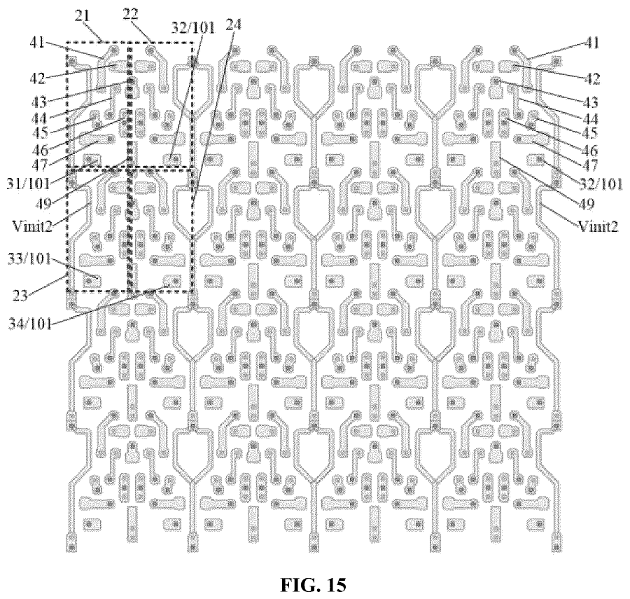

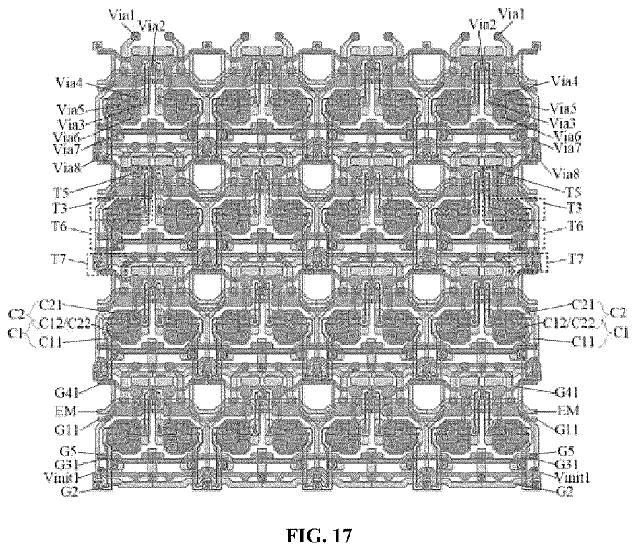

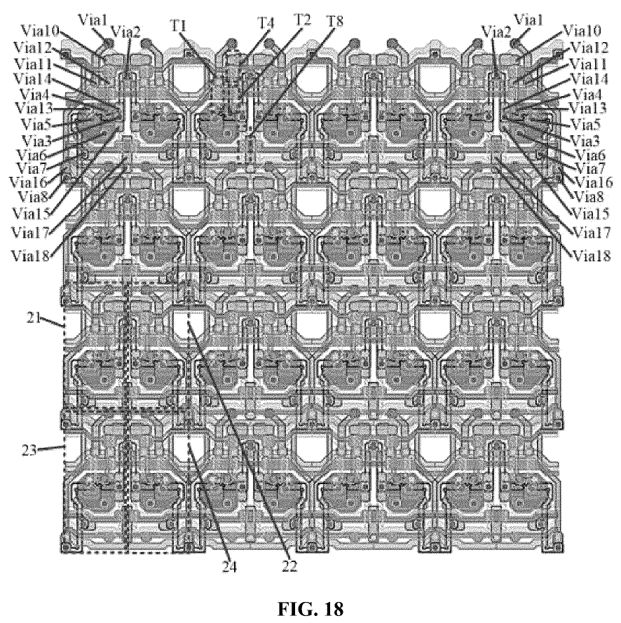

As shown in FIGS. 1 and 5 to 18, the subpixel driving circuit includes a first transistor T1, a second transistor T2, a third transistor T3, a fourth transistor T4, a fifth transistor T5, a sixth transistor T6, a seventh transistor T7, an eighth transistor T8, a first capacitor C1 and a second capacitor C2. The first transistor T1, the second transistor T2, the fourth transistor T4 and the eighth transistor T8 are N-channel Metal Oxide Semiconductor (NMOS) transistors, and the third transistor T3, the fifth transistor T5, the sixth transistor T6 and the seventh transistor T7 are P-channel Metal Oxide Semiconductor (PMOS) transistors.

The display substrate further includes a power source line VDD, a light-emission control signal line EM, a data line DA, a first scanning line G1, a second scanning line G2, a third scanning line G3, a fourth scanning line G4, a fifth scanning line G5, a first initialization signal line Vinit1, a second initialization signal line Vinit2, and a third initialization signal line Vinit3.

A gate electrode of the first transistor T1 is coupled to a corresponding first scanning line G1, a first electrode of the first transistor T1 is coupled to the first initialization signal line Vinit1, and a second electrode of the first transistor T1 is coupled to a gate electrode of the third transistor T3.

A gate electrode of the second transistor T2 is coupled a corresponding first scanning line G1, a first electrode of the second transistor T2 is coupled to a first electrode of the third transistor T3, and a second electrode of the second transistor T2 is coupled to a second plate C12 of the first capacitor C1.

A gate electrode of the fourth transistor T3 is coupled to a corresponding fourth scanning line G4, a first electrode of the fourth transistor T4 is coupled to a corresponding data line DA, and a second electrode of the fourth transistor 4 is coupled to the second electrode of the second transistor T2.

A gate electrode of the fifth transistor T5 is coupled to a corresponding light-emission control signal line EM, a first electrode of the fifth transistor T5 is coupled to the power source line VDD, and a second electrode of the fifth transistor T5 is coupled to the first electrode of the third transistor T3.

A gate electrode of the sixth transistor T6 is coupled to a corresponding fifth scanning line G5, a first electrode of the sixth transistor T6 is coupled to a second electrode of the third transistor T3, a second electrode of the sixth transistor T6 is coupled to an anode pattern of a corresponding light-emitting element, and a cathode of the light-emitting element is configured to receive a power source signal VSS.

A gate electrode of the seventh transistor T7 is coupled to a corresponding second scanning line G2, a first electrode of the seventh transistor T7 is coupled to the second initialization signal line Vinit2, and a second electrode of the seventh transistor T7 is coupled to an anode pattern of a corresponding light-emitting element.

A gate electrode of the eighth transistor T8 is coupled to a corresponding third scanning line G3, a first electrode of the eighth transistor T8 is coupled to the third initialization signal line Vinit3, and a second electrode of the eighth transistor T8 is coupled to the first electrode of the third transistor T3. For example, a scanning signal transmitted by the third scanning line G3 is identical to a scanning signal transmitted by the fifth scanning line G5, and the third scanning line G3 and the fifth scanning line G5 are coupled to a shift register unit at a peripheral region of the display substrate.

The first plate C11 of the first capacitor C1 is coupled to the power source line VDD. A first plate C21 of the second capacitor C2 is coupled to the gate electrode of the third transistor T3, and a second plate C22 of the second capacitor C2 is coupled to a second plate C12 of the first capacitor C1.

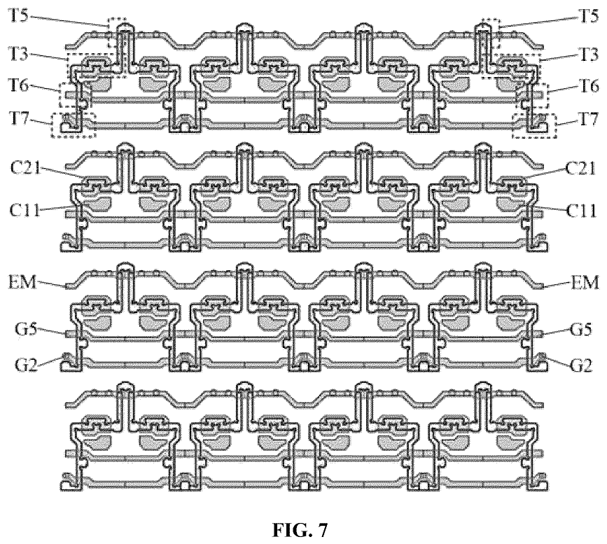

As shown in FIG. 7, an overlapping portion between a first active layer and a first gate metal layer forms a channel portion of a corresponding transistor.

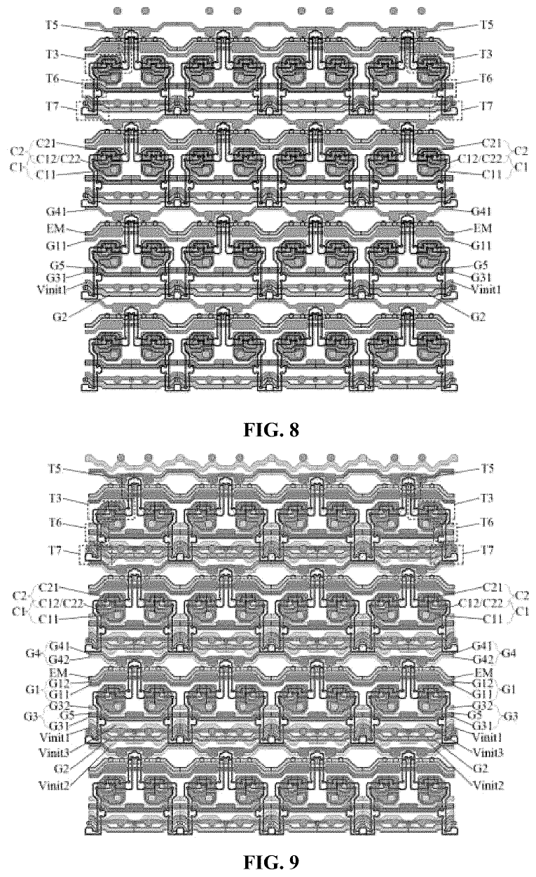

As shown in FIGS. 8, 9 and 10, the first scanning line G1 includes a first scanning layer G11 and a second scanning line G12. The third scanning line G3 includes a third scanning layer G31 and a fourth scanning layer G32. The fourth scanning line G4 includes a fifth scanning layer G41 and a sixth scanning layer G42. The first scanning layer G11, the third scanning layer G31 and the fifth scanning layer G41 are made of a second gate metal layer. The second scanning layer G12, the fourth scanning layer G32 and the sixth scanning layer G42 are made of a third gate metal layer.

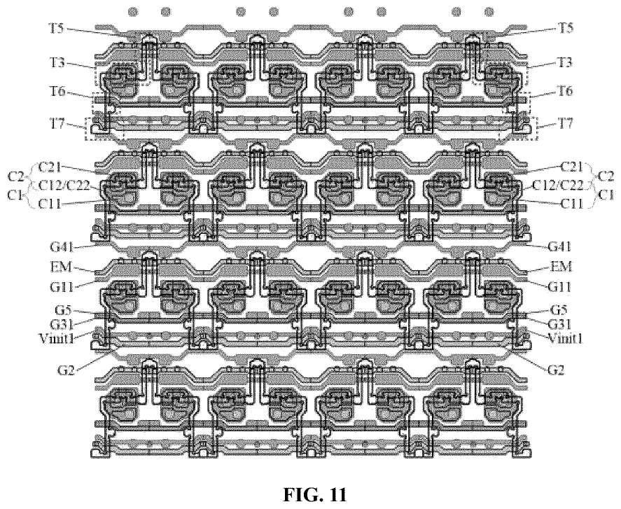

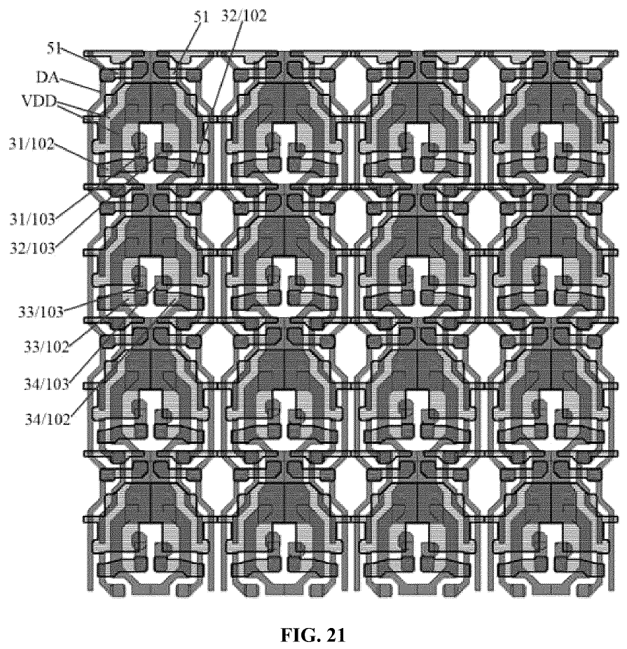

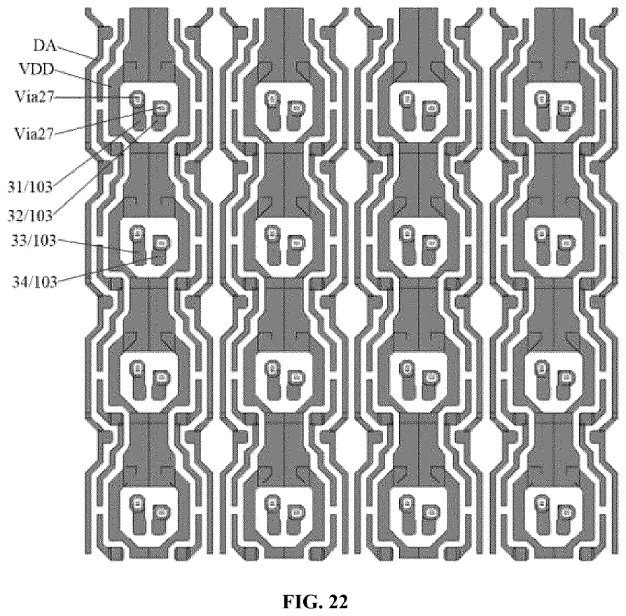

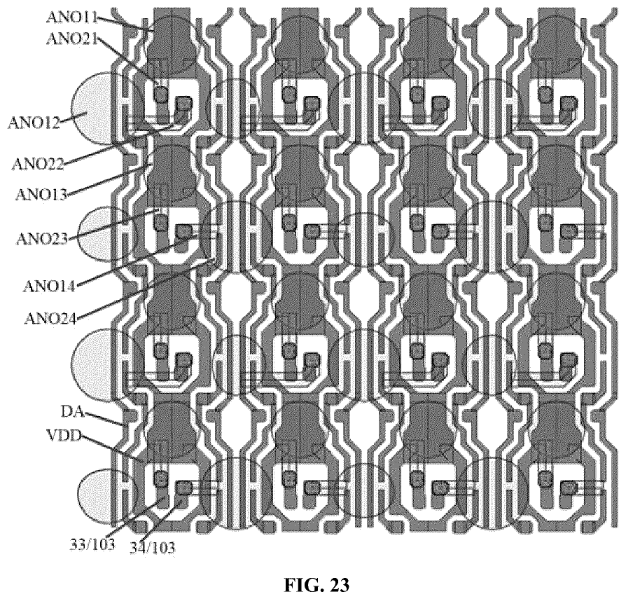

As shown in FIGS. 11 to 24, a first adapter member 41 is coupled to the first initialization signal line Vinit1 through a first via-hole Vial, and the first adapter member 41 is coupled to the first electrode of the first transistor T1 through an eleventh via-hole Via11.

A second adapter member 42 is coupled to the first electrode of the fourth transistor T4 through a tenth via-hole Via10, the second adapter member 42 is coupled to an eleventh adapter member 51 through a twenty-first via-hole Via21, and the eleventh adapter member 51 is coupled to the data line DA through a twenty-fourth a via-hole Via24.

A third adapter member 43 is coupled to the first electrode of the fifth transistor T5, the third adapter member 43 is coupled to a power source line VDD at a second source/drain metal layer through a twentieth via-hole Via20, and the power source line VDD at the second source/drain metal layer is coupled to a power source line VDD at a third source/drain metal layer through a twenty-sixth via-hole Via26.

A fourth adapter member 44 is coupled to the second plate C22 of the second capacitor C2 through a fourth via-hole Via4, and the fourth adapter member 44 is coupled to the second electrode of the fourth transistor T4 through a twelfth via-hole Via12.

A fifth adapter member 45 is coupled to the first plate C21 of the second capacitor C2 through a fifth via-hole Via5, and the fifth adapter member 45 is coupled to the second electrode of the first transistor T1 through a thirteenth via-hole Via13.

A sixth adapter member 46 is coupled to the first electrode of the second transistor T2 through a fourteenth via-hole Via14, and the sixth adapter member 46 is coupled to the second electrode of the eighth transistor T8 through a fifteenth via-hole Via15. The sixth adapter member 46 is coupled to the first electrode of the third transistor T3 through a third via-hole Via3.

A seventh adapter member 47 is coupled to the first plate C11 of the first capacitor C1 through a sixth via-hole Via6, and the seventh adapter member 47 is coupled to the power source line VDD at the second source/drain metal layer through a twenty-third via-hole Via23.

A ninth adapter member 49 is coupled to the first electrode of the eighth transistor T8 through a seventeenth via-hole Via17, and the ninth adapter member 49 is coupled to the third initialization signal line Vinit3 through an eighteenth via-hole Via18.

The first conductive connection member 101 is coupled to the second electrode of the sixth transistor T6 and the second electrode of the seventh transistor T7 through a seventh via-hole Via7, the first conductive connection member 101 is coupled to the second conductive connection member 102 through a twenty-second via-hole Via22, the second conductive connection member 102 is coupled to the third conductive connection member 103 through twenty-fifth via-hole Via25, and the third conductive connection member 103 is coupled to the anode extension member ANO2 through a twenty-seventh Via27.

The second initialization signal line Vinit2 at the first source/drain metal layer is coupled to the second initialization signal line Vinit2 at the second metal layer through a sixteenth via-hole Via16. The second initialization signal line Vinit2 at the first source/drain metal layer is coupled to the second electrode of the seventh transistor T7 through an eighth via-hole Via8.

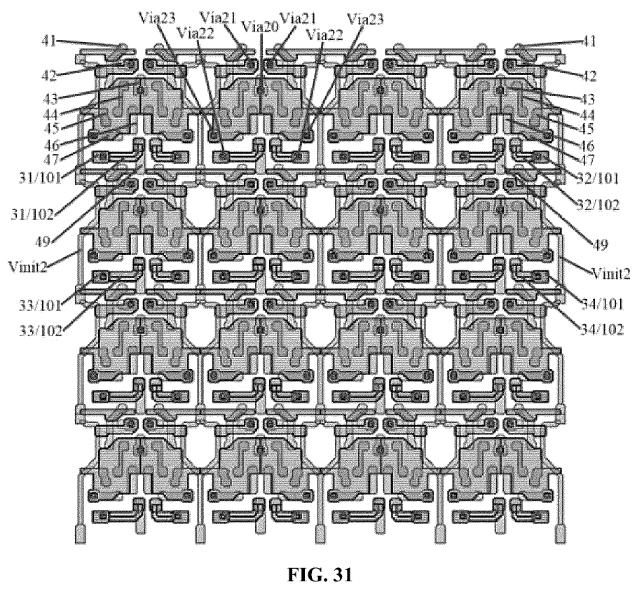

As shown in FIGS. 16, 19, 23, 24, 25, 29, 30, 31, 35 and 36, in some embodiments of the present disclosure, the conductive connection structure includes a first conductive connection member 101, a second conductive connection member 102 and a third conductive connection member 103 laminated one on another in a direction away from the base substrate. The second conductive connection member 102 is coupled to the first conductive connection member 101 and the third conductive connection member 103, the first conductive connection member 101 is coupled to the second electrode of the light-emission control transistor, and the third conductive connection member 103 is coupled to the anode extension member.

An orthogonal projection of the first conductive connection member 101 onto the base substrate does not overlap with an orthogonal projection of the third conductive connection member 103 onto the base substrate.

For example, the orthogonal projection of the first conductive connection member 101 onto the base substrate at least partially does not overlap with the orthogonal projection of the third conductive connection member 103 onto the base substrate.

For example, the orthogonal projection of the first conductive connection member 101 onto the base substrate completely does not overlap with the orthogonal projection of the third conductive connection member 103 onto the base substrate.

For example, an orthogonal projection of the second conductive connection member 102 onto the base substrate overlaps with the orthogonal projection of the first conductive connection member 101 onto the base substrate at an overlapping region, and the second conductive connection member 102 is electrically coupled to the first conductive connection member 101 through a via-hole in the overlapping region. The orthogonal projection of the second conductive connection member 102 onto the base substrate overlaps with the orthogonal projection of the third conductive connection member 103 onto the base substrate at an overlapping region, and the second conductive connection member 102 is electrically coupled to the third conductive connection member 103 through a via-hole in the overlapping region.

In the display device provided in the embodiments of the present disclosure, the conductive connection structure includes the first conductive connection member 101, the second conductive connection member 102 and the third conductive connection member 103 laminated one on another in a direction away from the base substrate. Through the arrangement of the first conductive connection member 101, the second conductive connection member 102 and the third conductive connection member 103, it is able to implement the conductive connection structure in more diversified layout modes, and select a position of the anode pattern coupled to the conductive connection structure in a more flexible manner, thereby to effectively reduce a layout difficulty of the display substrate.

In the display device provided in the embodiments of the present disclosure, in a case that the orthogonal projection of the first conductive connection member 101 onto the base substrate does not overlap with the orthogonal projection of the third conductive connection member 103 onto the base substrate, the conductive connection structure may extend much further in a direction parallel to the base substrate, so it is able to further improve the flexibility of the position layout of the anode pattern coupled to the conductive connection structure, thereby to further reduce the layout difficulty of the display substrate.

In some embodiments of the present disclosure, the display substrate includes a firs source/drain metal layer, a second source/drain metal layer and a third source/drain metal layer laminated one on another in a direction away from the base substrate. The first conductive connection member 101 is arranged at a same layer, and made of a same material, as the first source/drain metal layer, the second conductive connection member 102 is arranged at a same layer, and made of a same material, as the second source/drain metal layer, and the third conductive connection member 103 is arranged at a same layer, and made of a same material, as the third source/drain metal layer.

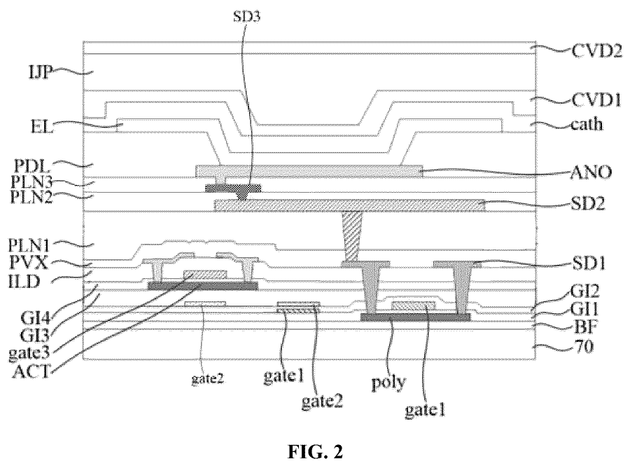

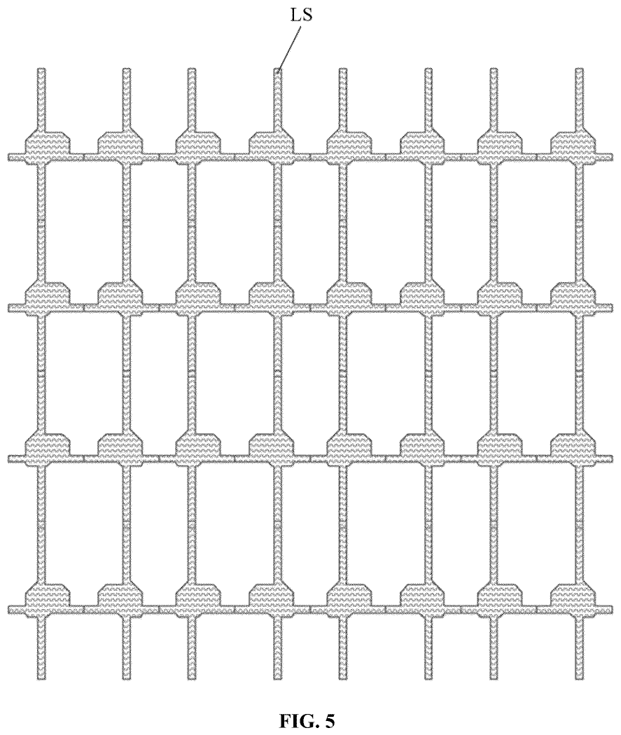

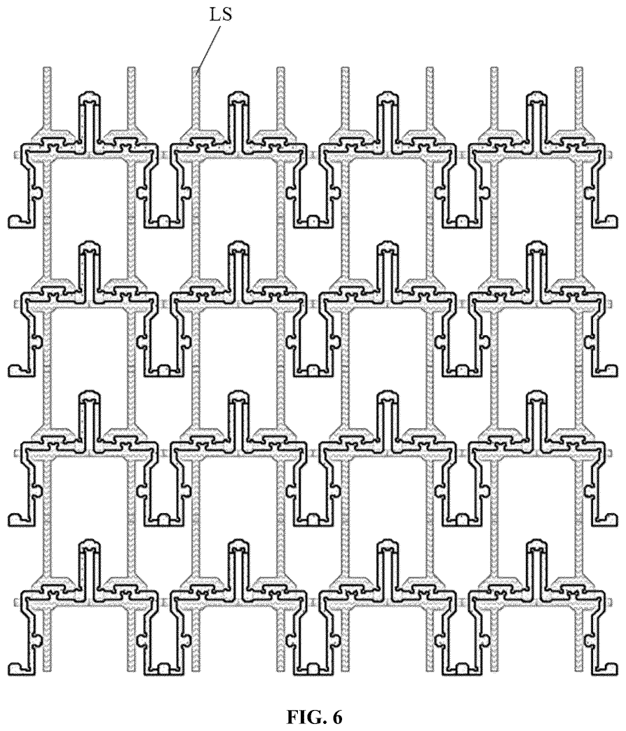

As shown in FIG. 2, for example, the display substrate includes a buffer layer BF, a first active layer poly, a first gate insulation layer GI1, a first gate metal layer gate1, a second gate insulation layer GI2, a second gate metal layer gate2, a third gate insulation layer GI3, a second active layer ACT, a fourth gate insulation layer GI4, a third gate metal layer gate3, an interlayer insulation layer ILD, a first source/drain metal layer SD1, a passivation layer PVX, a first planarization layer PLN1, a second source/drain metal layer SD2, a second planarization layer PLN2, a third source/drain metal layer SD3, a third planarization layer PLN3, an anode layer ANO, a pixel definition layer PDL, a light-emitting functional layer EL, a cathode layer cath, a first inorganic encapsulation layer CVD1, an organic encapsulation layer IJP, and a second inorganic encapsulation layer CVD2 laminated one on another in a direction away from the base substrate 70. As shown in FIGS. 5 and 6, the display substrate further includes a light-shielding layer LS arranged between the first active layer poly and the base substrate 70. The light-shielding layer LS is configured to shield a channel portion of the third transistor T3, so as to improve the stability of the third transistor T3.

Based on the arrangement, the first conductive connection member 101 and the first source/drain metal layer are formed simultaneously in a single patterning process, the second conductive connection member 102 and the second source/drain metal layer are formed simultaneously in a single patterning process, and the third conductive connection member 103 and the third source/drain metal layer are formed simultaneously in a single patterning process, so as to simplify a manufacture process of the display substrate, and reduce the manufacture cost.

As shown in FIGS. 3 and 4, in some embodiments of the present disclosure, the plurality of driving circuit columns includes a plurality of driving circuit groups QLZ arranged in the second direction, the driving circuit group QLZ includes a first driving circuit column QL1 and a second driving circuit column QL2 proximate to each other, the driving circuit group includes first driving units QD1 and second driving units QD2 arranged alternately in the first direction, the first driving unit QD1 includes a first subpixel driving circuit (e.g., a green subpixel driving circuit P_G) and a second subpixel driving circuit (e.g., a blue subpixel driving circuit P_B and a red subpixel driving circuit P_R) arranged sequentially in the second direction, and the second driving unit QD2 includes a third subpixel driving circuit (e.g., the green subpixel driving circuit P_G) and a fourth subpixel driving circuit (e.g., the blue subpixel driving circuit P_B and the red subpixel driving circuit P_R) arranged sequentially in the second direction.

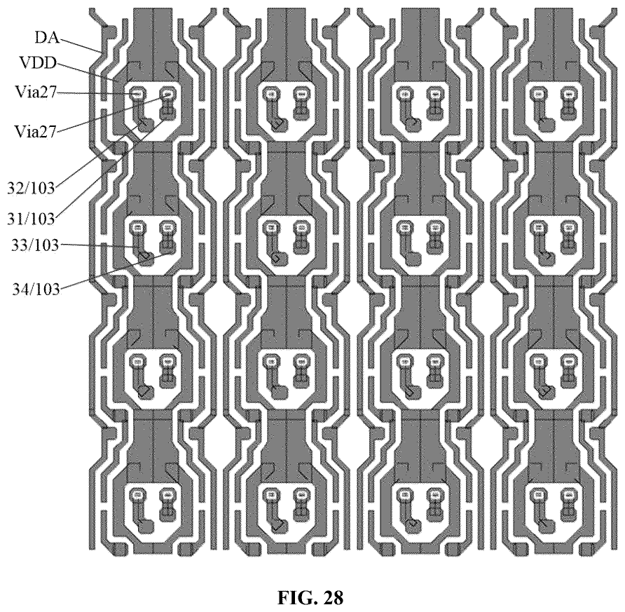

As shown in FIGS. 16 and 19 to 36, the first subpixel driving circuit is coupled to a first anode extension member ANO21 via a first conductive connection structure 31, the second subpixel driving circuit is coupled to a second anode extension member ANO22 via a second conductive connection structure 32, the third subpixel driving circuit is coupled to a third anode extension member ANO23 via a third conductive connection structure 33, and the fourth subpixel driving circuit is coupled to a fourth anode extension member ANO24 via a fourth conductive connection structure 34.

An orthogonal projection of the first anode extension member ANO21 onto the base substrate does not overlap with an orthogonal projection of the second conductive connection structure 32 onto the base substrate, and/or an orthogonal projection of the third anode extension member ANO23 onto the base substrate does not overlap with an orthogonal projection of the fourth conductive connection structure 34 onto the base substrate.

It should be appreciated that, the first subpixel driving circuit is arranged in a first subpixel driving circuit layout region 21, the second subpixel driving circuit is arranged in a second subpixel driving circuit layout region 22, the third subpixel driving circuit is arranged in a third subpixel driving circuit layout region 23, and the fourth subpixel driving circuit is arranged in a fourth subpixel driving circuit layout region 24.

For example, each of the first conductive connection structure 31, the second conductive connection structure 32, the third conductive connection structure 33 and the fourth conductive connection structure 34 may include the first conductive connection member 101, the second conductive connection member 102 and the third conductive connection member 103. However, the first conductive connection members 101 belonging to different conductive connection structures may be the same or different, the second conductive connection members 102 belonging to different conductive connection structures may be the same or different, and the third conductive connection members 103 belonging to different conductive connection structures may be the same or different.

For example, the light-emitting element to which the first anode extension member ANO21 belongs includes a green light-emitting element, the light-emitting element to which the second anode extension member ANO22 belongs includes a red light-emitting element or a blue light-emitting element, the light-emitting element to which the third anode extension member ANO23 belongs includes a green light-emitting element, and the light-emitting element to which the fourth anode extension member ANO24 belongs includes a red light-emitting element or a blue light-emitting element.

For example, the first anode extension member ANO21 is coupled to the first anode body ANO11 to form a first anode pattern. An overlapping area between an orthogonal projection of the first anode body ANO11 onto the base substrate and an orthogonal projection of the power source line VDD on the display substrate onto the base substrate is greater than or equal to 50% of an area of the first anode body ANO11.

For example, the third anode extension member ANO23 is coupled to the third anode body ANO13 to form a third anode pattern. An overlapping area between an orthogonal projection of the third anode body ANO13 onto the base substrate and the orthogonal projection of the power source line VDD on the display substrate onto the base substrate is greater than or equal to 50% of an area of the third anode body ANO13.

For example, the second anode extension member ANO22 is coupled to the second anode body ANO12 to form a second anode pattern. An overlapping area between an orthogonal projection of the second anode body ANO12 onto the base substrate and the orthogonal projection of the power source line VDD on the display substrate onto the base substrate is greater than or equal to 30% of an area of the second anode body ANO12.

For example, the fourth anode extension member ANO24 is coupled to the fourth anode body ANO14 to form a fourth anode pattern. An overlapping area between an orthogonal projection of the fourth anode body ANO14 onto the base substrate and the orthogonal projection of the power source line VDD on the display substrate onto the base substrate is greater than or equal to 50% of an area of the fourth anode body ANO14.

Based on the above, in a case that the orthogonal projection of the first anode extension member ANO21 onto the base substrate does not overlap with the orthogonal projection of the second conductive connection structure 32 onto the base substrate and/or an orthogonal projection of the third anode extension member ANO23 onto the base substrate does not overlap with the orthogonal projection of the fourth conductive connection structure 34 onto the base substrate, it is able to prevent the first anode pattern and the third anode pattern from occupying a layout space of an adjacent anode pattern in a better manner, thereby to ensure the layout reliability in a case of utilizing the layout space appropriately. In addition, based on the above arrangement, it is able to achieve the diamond-like arrangement mode of the light-emitting elements, and enable the light-emitting elements coupled to one driving circuit column coupled to the data line DA to emit light in a same column.

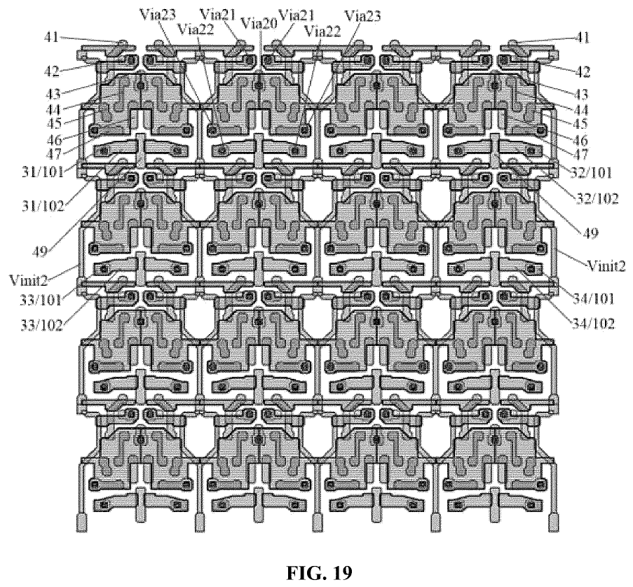

As shown in FIGS. 19 to 24, in some embodiments of the present disclosure, the orthogonal projection of the first anode extension member ANO21 onto the base substrate does not overlap with the orthogonal projection of the first conductive connection member 101 in the first conductive connection structure 31 onto the base substrate, and/or the orthogonal projection of the first anode extension member ANO21 onto the base substrate does not overlap with an orthogonal projection of the second conductive connection member 102 in the first conductive connection structure 31 onto the base substrate.

Based on the above arrangement, the first anode body ANO11 may be arranged at a region surrounding the first conductive connection member 101 and/or the second conductive connection member 102 coupled to the first anode body ANO11, so as to effectively increase a layout space for the first anode body ANO11, thereby to reduce the layout difficulty of the display substrate. In addition, based on the above arrangement, it is able to achieve the diamond-like arrangement mode of the light-emitting elements, and enable the light-emitting elements coupled to one driving circuit column coupled to the data line DA to emit light in a same color.

As shown in FIGS. 19 to 24, in some embodiments of the present disclosure, the orthogonal projection of the third anode extension member ANO23 onto the base substrate does not overlap with the orthogonal projection of the first conductive connection member 101 in the third conductive connection structure 33 onto the base substrate, and/or the orthogonal projection of the third anode extension member ANO23 onto the base substrate does not overlap with an orthogonal projection of the second conductive connection member 102 in the third conductive connection structure 33 onto the base substrate.

Based on the above arrangement, the third anode body ANO13 may be arranged at a region surrounding the first conductive connection member 101 and/or the second conductive connection member 102 coupled to the third anode body ANO13, so as to effectively increase a layout space for the third anode body ANO13, thereby to reduce the layout difficulty of the display substrate. In addition, based on the above arrangement, it is able to achieve the diamond-like arrangement mode of the light-emitting elements, and enable the light-emitting elements coupled to one driving circuit column coupled to the data line DA to emit light in a same color.

As shown in FIGS. 19 to 24, in some embodiments of the present disclosure, an orthogonal projection of the second anode extension member ANO22 onto the base substrate at least partially overlaps with an orthogonal projection of the first conductive connection structure 31 onto the base substrate.

For example, the orthogonal projection of the second anode extension member ANO22 onto the base substrate at least partially overlaps with the orthogonal projection of the second conductive connection member 102 in the first conductive connection structure 31 onto the base substrate, and/or the orthogonal projection of the second anode extension member ANO22 onto the base substrate at least partially overlaps with the orthogonal projection of the third conductive connection member 103 in the first conductive connection structure 31 onto the base substrate.

Based on the above arrangement, the second anode body ANO12 may be arranged in the vicinity of the first conductive connection structure 31, so as to achieve the diamond-like arrangement mode of the light-emitting elements, and enable the light-emitting elements coupled to one driving circuit column coupled to the data line DA to emit light in a same color.

As shown in FIGS. 19 to 24, in some embodiments of the present disclosure, the orthogonal projection of the second anode extension member ANO22 onto the base substrate does not overlap with the orthogonal projection the first conductive connection member 101 in the second conductive connection structure 32 onto the base substrate, and/or the orthogonal projection of the second anode extension member ANO22 onto the base substrate at least partially overlaps with the orthogonal projection the second conductive connection member 102 in the second conductive connection structure 32 onto the base substrate.

Based on the above arrangement, the second anode extension member ANO22 may occupy a part of the space in the vicinity of the second conductive connection structure 32, so as to effectively reduce the layout difficulty of the second anode extension member ANO22.

As shown in FIGS. 19 to 24, in some embodiments of the present disclosure, the second conductive connection member 102 in the first conductive connection structure 31 is arranged symmetrical with the second conductive connection member 102 in the second conductive connection structure 32, and/or the second conductive connection member 102 in the third conductive connection structure 33 is arranged symmetrical with the second conductive connection member 102 in the fourth conductive connection structure 34.

Based on the above arrangement, it is able to improve the uniformity of the display substrate while achieving the diamond-like arrangement mode of the light-emitting elements and enabling the light-emitting elements coupled to one driving circuit column coupled to the data line DA to emit light in a same color.

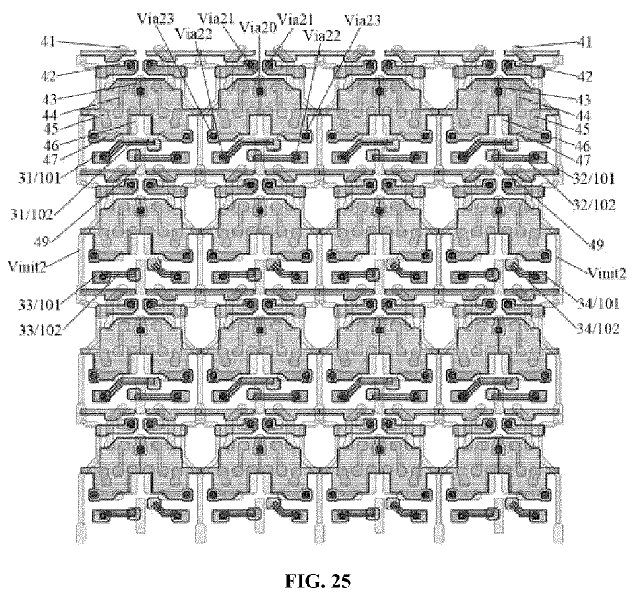

As shown in FIGS. 25 to 36, in some embodiments of the present disclosure, an orthogonal projection of the second anode extension member ANO22 onto the base substrate does not overlap with an orthogonal projection of the first conductive connection structure 31 onto the base substrate.

As shown in FIGS. 25 to 36, in some embodiments of the present disclosure, an orthogonal projection of the second anode body ANO12 onto the base substrate at least partially overlaps with the orthogonal projection of the first conductive connection member 101 in an adjacent second conductive connection structure 32 onto the base substrate, and/or the orthogonal projection of the second anode body ANO12 onto the base substrate at least partially overlaps with the orthogonal projection of the second conductive connection member 102 in the adjacent second conductive connection structure 32 onto the base substrate. The adjacent second conductive connection structure 32 and the second conductive connection structure coupled to the second anode extension member ANO12 are arranged in the second direction.

Based on the above arrangement, the second anode body ANO12 may occupy the layout space for the adjacent subpixel driving circuit, so as to effectively reduce the layout difficulty of the second anode body ANO12.

As shown in FIGS. 25 to 36, in some embodiments of the present disclosure, the orthogonal projection of the third conductive connection member 103 in the second conductive connection structure 32 onto the base substrate at least partially overlaps with the orthogonal projection of the second conductive connection member 102 in the first conductive connection structure 31 onto the base substrate; and/or the orthogonal projection of the second conductive connection member 102 in the second conductive connection structure 32 onto the base substrate does not overlap with the orthogonal projection of the third conductive connection member 103 in the first conductive connection structure 31 onto the base substrate.

Based on the above arrangement, it is able to effectively increase a layout space to be utilized by the anode pattern, thereby to reduce the layout difficulty of the display substrate. In addition, it is able to achieve the diamond-like arrangement mode of the light-emitting elements, and enable the light-emitting elements coupled to one driving circuit column coupled to the data line DA to emit light in a same color.

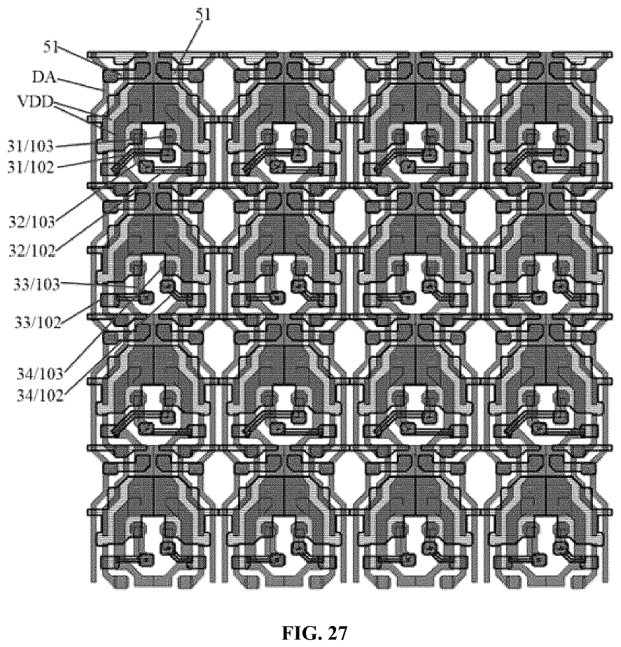

As shown in FIG. 27, in some embodiments of the present disclosure, at least a portion of the third conductive connection member 103 in the first conductive connection structure 31 extends in the first direction, at least a portion of the second conductive connection member 102 in the second conductive connection structure 32 extends in the second direction, and the orthogonal projection of the third conductive connection member 103 in the first conductive connection structure 31 onto the base substrate and the orthogonal projection of the second conductive connection member 102 in the second conductive connection structure 32 onto the base substrate are arranged in the first direction.

Based on the above arrangement, it is able to effectively increase a layout space to be utilized by the anode pattern, thereby to reduce the layout difficulty of the display substrate. In addition, it is able to achieve the diamond-like arrangement mode of the light-emitting elements, and enable the light-emitting elements coupled to one driving circuit column coupled to the data line DA to emit light in a same color.

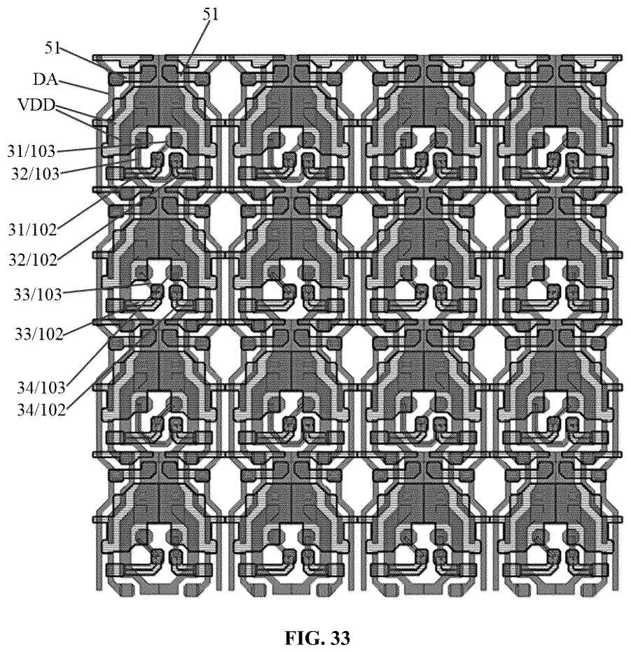

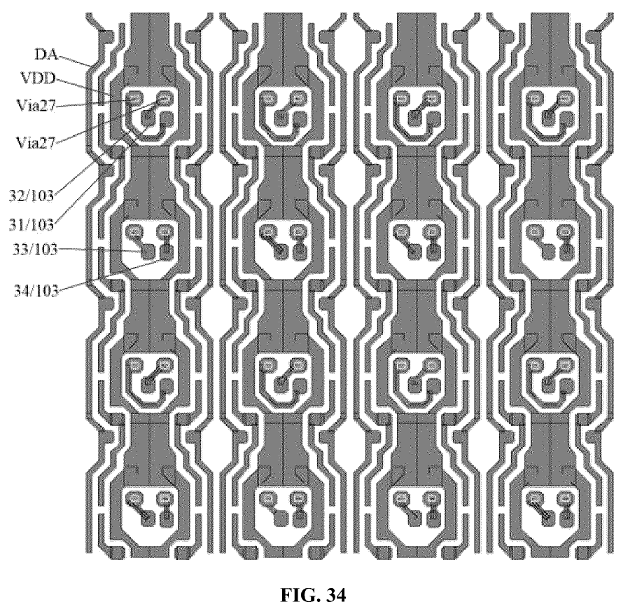

As shown in FIG. 33, in some embodiments of the present disclosure, at least a portion of the third conductive connection member 103 in the first conductive connection structure 31 extends in a third direction, the third direction intersects the first direction and the second direction, and one end of the third conductive connection member 103 in the first conductive connection structure 31 is at least partially surrounded by the third conductive connection member 103 in the second conductive connection structure 32.

Based on the above arrangement, it is able to achieve the diamond-like arrangement mode of the light-emitting elements, and enable the light-emitting elements coupled to one driving circuit column coupled to the data line DA to emit light in a same color. In addition, it is able to effectively increase a layout space to be utilized by the anode pattern, thereby to reduce the layout difficulty of the display substrate.

Based on the above arrangement, it is able to effectively increase a layout space to be utilized by the anode pattern, thereby to reduce the layout difficulty of the display substrate. In addition, it is able to achieve the diamond-like arrangement mode of the light-emitting elements, and enable the light-emitting elements coupled to one driving circuit column coupled to the data line DA to emit light in a same color.

As shown in FIGS. 19 to 36, an orthogonal projection of the fourth anode extension member ANO24 onto the base substrate does not overlap with the orthogonal projection of the third conductive connection structure 33 onto the base substrate.

As shown in FIGS. 19 to 36, the orthogonal projection of the fourth anode extension member ANO24 onto the base substrate does not overlap with the orthogonal projection of the first conductive connection member 101 in the fourth conductive connection structure 34 onto the base substrate, and/or the orthogonal projection of the fourth anode extension member ANO24 onto the base substrate does not overlap with the orthogonal projection of the second conductive connection member 102 in the fourth conductive connection structure 34 onto the base substrate.

As shown in FIGS. 19 to 36, the fourth anode extension member ANO24 includes at least a portion extending in the second direction, the second conductive connection member 102 in the fourth conductive connection structure 34 includes at least a portion extending in the second direction, and the orthogonal projection of the fourth anode extension member ANO24 onto the base substrate and the orthogonal projection of the second conductive connection member 102 in the fourth conductive connection structure 34 onto the base substrate are arranged in the first direction.

Based on the above arrangement, it is able to effectively increase a layout space to be utilized by the anode pattern, thereby to reduce the layout difficulty of the display substrate. In addition, it is able to achieve the diamond-like arrangement mode of the light-emitting elements, and enable the light-emitting elements coupled to one driving circuit column coupled to the data line DA to emit light in a same color.

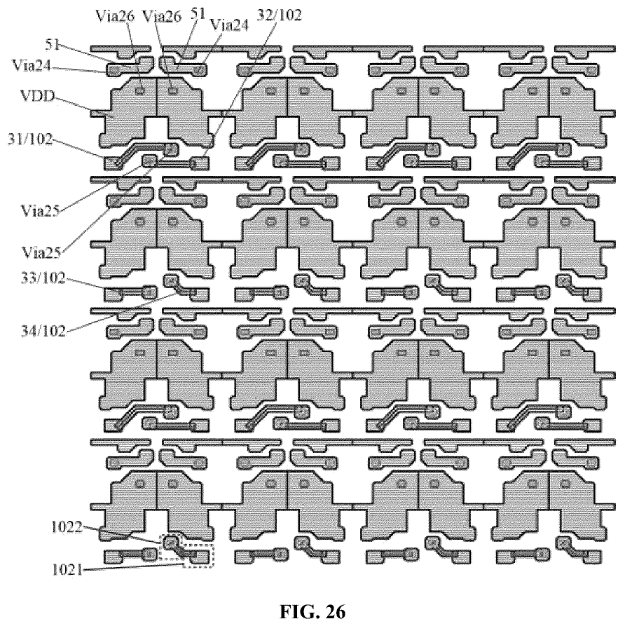

As shown in FIGS. 26 and 27, in some embodiments of the present disclosure, the third conductive connection member 103 in the fourth conductive connection structure 34 includes at least a portion extending the first direction, the second conductive connection member 102 in the fourth conductive connection structure 34 includes a first sub-portion 1021 and a second sub-portion 1022 coupled to each other, the first sub-portion 1021 extends in the second direction, an extension direction of the second sub-portion 1022 intersects the first direction, the first sub-portion 1021 is coupled to the first conductive connection member 101, and the second sub-portion 1022 is coupled to the third conductive connection member 103.

As shown in FIGS. 26 and 27, in some embodiments of the present disclosure, the first sub-portion 1021 and the second conductive connection member 102 in the first conductive connection structure 31 are arranged in the second direction, and the second sub-portion 1022 is at least partially staggered with the second conductive connection member 102 in the first conductive connection structure 31 in the first direction.

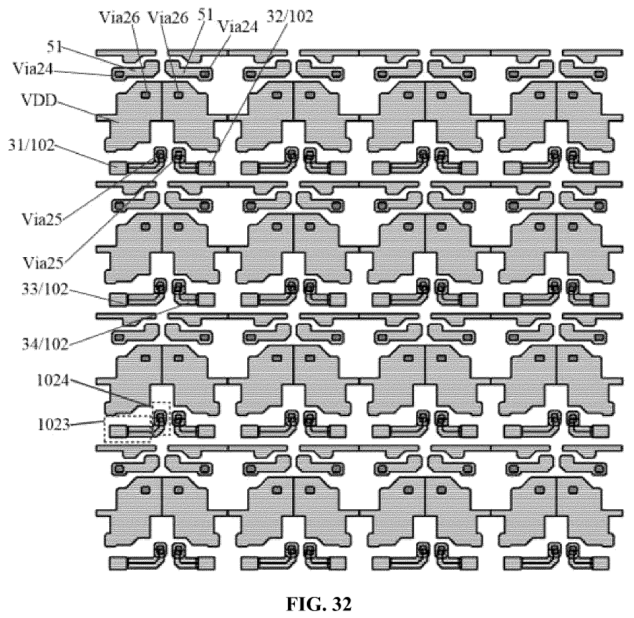

As shown in FIGS. 32 and 33, an extension direction of the third conductive connection member 103 in the first conductive connection structure 31 intersects the first direction, the second conductive connection member 102 in the first conductive connection structure 31 includes a third sub-portion 1023 and a fourth sub-portion 1024 coupled to each other, the third sub-portion 1023 is coupled to the first conductive connection member 101, the fourth sub-portion 1024 is coupled to the third conductive connection member 103, the third sub-portion 1023 extends in the second direction, an extension direction of the fourth sub-portion 1024 intersects an extension direction of the third sub-portion 1023, the third sub-portion 1023 and the first sub-portion 1021 are arranged in the second direction, and the fourth sub-portion 1024 and the second sub-portion 1022 are arranged in the second direction.

In the display substrate provided in the above embodiments of the present disclosure, in a case that the above arrangement mode is used, at least a part of the red light-emitting element R and at least a part of the blue light-emitting element B are arranged on the green subpixel driving circuit P_G, so that the green subpixel driving circuit P_G in a column of green subpixel driving circuits P_G may drive the corresponding green light-emitting element G on the right in the first direction.

In the display substrate provided in the above embodiments of the present disclosure, it is able for the blue subpixel driving circuits P_B in one column to drive the blue light-emitting elements B on the left and right in the first direction.

In the display substrate provided in the above embodiments of the present disclosure, it is able for the red subpixel driving circuits P_R in one column to drive the red light-emitting elements R on the left and right in the first direction.

Based on the above arrangement, it is able to effectively increase a layout space to be utilized by the anode pattern, thereby to reduce the layout difficulty of the display substrate. In addition, it is able to achieve the diamond-like arrangement mode of the light-emitting elements, and enable the light-emitting elements coupled to one driving circuit column coupled to the data line DA to emit light in a same color.

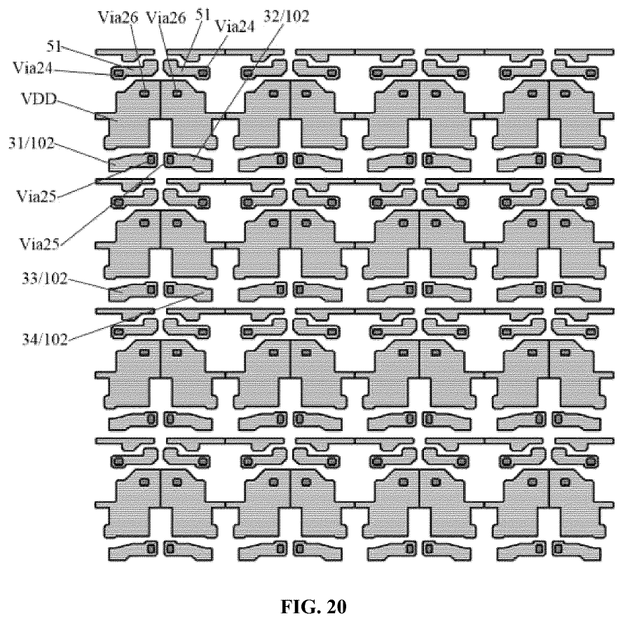

As shown in FIGS. 20 and 32, in some embodiments of the present disclosure, the second conductive connection member 102 in the first conductive connection structure 31 and the second conductive connection member 102 in the third conductive connection structure 33 extend in a same direction, and the second conductive connection member 102 in the second conductive connection structure 32 and the second conductive connection member 102 in the fourth conductive connection structure 34 extend in a same direction.

For example, in the first conductive connection structure 31, the second conductive connection member 102 has a first extension direction from the first conductive connection member 101 to the third conductive connection member 103, and in the second conductive connection structure 32, the second conductive connection member 102 has a second extension direction from the first conductive connection member 101 to the third conductive connection member 103, and the second extension direction is at least partially opposite to the first extension direction.

The present disclosure further provides in some embodiments a display substrate, which includes a base substrate, and a plurality of subpixels and a plurality of data lines arranged on the base substrate, each of subpixels including a subpixel driving circuit and a light-emitting element coupled to each other. A plurality of subpixel driving circuits included in the plurality of subpixels includes a plurality of driving circuit column, each of the driving circuit columns includes a plurality of subpixel driving circuits arranged in a first direction, light-emitting elements coupled to the subpixel driving circuits in a same driving circuit column emit light in a same color, and each of the data lines is coupled to the subpixel driving circuits in a corresponding driving circuit column. The plurality of driving circuit columns includes a plurality of first driving circuit columns and a plurality of second driving circuit columns, the plurality of first driving circuit columns and the plurality of second driving circuit columns are arranged alternately in a second direction, and the second direction intersects the first direction. The light-emitting elements coupled to the first driving circuit column are arranged in the first direction to form a first light-emitting element column, and the light-emitting elements coupled to the second diving circuit column are arranged in the first direction to form a second light-emitting element column. A driving transistor in the subpixel driving circuit includes an active pattern, the light-emitting element includes an anode pattern, the anode pattern includes an anode body and an anode extension member coupled to each other, and in a same light-emitting element column, an orthogonal projection of the anode body onto the base substrate does not overlap with an orthogonal projection of the active pattern of the driving transistor in the subpixel driving circuit coupled to the anode body onto the base substrate.

For example, the orthogonal projection of the anode body of the light-emitting element onto the base substrate does not overlap with an orthogonal projection of the subpixel driving circuit for driving the light-emitting element (including transistors in the subpixel driving circuit, e.g., an active layer of the transistor) onto the base substrate.

For example, an orthogonal projection of the first light-emitting element column onto the base substrate at least partially overlaps with an orthogonal projection of the second driving circuit column onto the base substrate, and an orthogonal projection of the second light-emitting element column onto the base substrate at least partially overlaps with an orthogonal projection of the first driving circuit column onto the base substrate.

Through arranging the subpixel driving circuits and the anode patterns in a column direction in a staggered manner, the data line coupled to the subpixel driving circuits in a same column merely needs to apply a data signal corresponding to the subpixels in a same color, so as to reduce the power consumption. In addition, for the subpixels in a same color, the light-emitting element is spaced apart from the subpixel driving circuit by an approximately equal distance, so it is able for the light-emitting elements to emit light more uniformly.

The present disclosure further provides in some embodiments a display device, which includes the above-mentioned display substrate.

It should be appreciated that, the display device may be any product or member having a display function, e.g., television, display, digital photo frame, mobile phone or tablet computer. The display device further includes a flexible circuit board, a printed circuit board and a back plate.

In the display substrate provided in the above embodiments of the present disclosure, the light-emitting elements in the plurality of subpixels form the light-emitting element repeat units each in the diamond-like arrangement mode. In addition, the plurality of subpixel driving circuits in the plurality of subpixels includes the plurality of driving circuit columns, the driving circuit column includes a plurality of subpixel driving circuits arranged in the first direction, the light-emitting elements coupled to the subpixel driving circuits in a same driving circuit column emit light in a same color, and the data line DA is coupled to the subpixel driving circuits in a corresponding driving circuit column. The light-emitting elements coupled to the subpixel driving circuits in a driving circuit column coupled to the data line DA emit light in a same color, so in a case that the subpixels are scanned by a shift register unit row by row, i.e., in a case that the data line DA provides data signals to the subpixels in one column sequentially, a voltage of the data signal transmitted via the data line DA changes within a very tiny range or does not change. In this way, a driving chip does not need to charge the data signal repeatedly in a jumping manner, and the data line DA provides the data signal within a corresponding range to the subpixels coupled to the data line DA, so as to effectively reduce the power consumption of the driving chip, thereby to reduce the overall power consumption of the display product. Hence, in the display substrate according to the embodiments of the present disclosure, in a case of the diamond-like arrangement mode, it is able to reduce the power consumption of the driving chip, thereby to reduce the overall power consumption of the display product.

In a case that the display device includes the display substrate, it also has the above-mentioned beneficial effects, which will not be particularly defined herein.

It should be appreciated that, in the case that a signal line extends along a direction X, it means that a primary portion of the signal line, e.g., a line, a segment or a strip-like body, extends along the direction X, and an extension length of the primary portion is greater than an extension length of a secondary portion of the signal line, which is coupled to the primary portion, in the other direction.

It should be further appreciated that, the expression “at a same layer” refers to that the film layers are arranged on a same structural layer. Alternatively, for example, the film layers on a same layer may be layer structures formed through forming thin layers for forming specific patterns through a single-film-forming process and then patterning the film layers with a same mask through a single patterning process. Depending on different specific patterns, a single patterning process may include multiple exposing, development or etching processes, and the specific patterns in the layer structure may be continuous or discontinuous. These specific patterns may also be arranged at different levels or have different thicknesses.

In the embodiments of the present disclosure, the order of the steps is not limited to the serial numbers thereof. For a person skilled in the art, any change in the order of the steps shall also fall within the scope of the present disclosure if without any creative effort.

It should be further appreciated that, the above embodiments have been described in a progressive manner, and the same or similar contents in the embodiments have not been repeated, i.e., each embodiment has merely focused on the difference from the others. Especially, the method embodiments are substantially similar to the product embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The above embodiments are for illustrative purposes only, but the present disclosure is not limited thereto. A person skilled in the art may make further alterations and replacements without departing from the spirit of the present disclosure, and these alterations and replacements shall also fall within the scope of the present disclosure. Hence, the scope of the present disclosure shall be subject to the scope of the appended claims.

1. A display substrate, comprising a base substrate, and a plurality of subpixels and a plurality of data lines arranged on the base substrate, each of the subpixels comprising a subpixel driving circuit and a light-emitting element coupled to each other, wherein
a plurality of subpixel driving circuits comprised in the plurality of subpixels comprises a plurality of driving circuit columns, each of the driving circuit columns comprises a plurality of subpixel driving circuits arranged in a first direction, light-emitting elements coupled to the subpixel driving circuits in a same driving circuit column emit light in a same color, and each of the data lines is coupled to the subpixel driving circuits in a corresponding driving circuit column;
the plurality of driving circuit columns comprises a plurality of first driving circuit columns and a plurality of second driving circuit columns, the plurality of first driving circuit columns and the plurality of second driving circuit columns are arranged alternately in a second direction, and the second direction intersects the first direction; and
the light-emitting elements coupled to the first driving circuit column are arranged in the first direction to form a first light-emitting element column, odd-numbered light-emitting elements in the light-emitting elements coupled to the second diving circuit column and even-numbered light-emitting elements in the light-emitting elements coupled to an adjacent second driving circuit column are arranged alternately in the first direction to form a second light-emitting element column, the second light-emitting element columns and the first light-emitting element columns are arranged alternately in the second direction, and the light-emitting elements in the first light-emitting element column are at least partially staggered with the light-emitting elements in the second light-emitting element column in the first direction.

2. The display substrate according to claim 1, wherein the plurality of subpixel driving circuits comprised in the plurality of subpixels comprises a plurality of driving circuit rows, and the driving circuit row comprises a plurality of subpixel driving circuits arranged in the second direction; and
the light-emitting elements coupled to odd-numbered subpixel driving circuits in the driving circuit row are arranged in the second direction to form a first light-emitting element row, the light-emitting elements coupled to even-numbered subpixel driving circuits in the driving circuit row are arranged in the second direction to form a second light-emitting element row, the first light-emitting element rows and the second light-emitting element rows are arranged alternately in the first direction, and the light-emitting elements in the first light-emitting element row are at least partially staggered with the light-emitting elements in the second light-emitting element row in the second direction.

3. The display substrate according to claim 2, wherein the first driving circuit column is coupled to first-color light-emitting elements, a first part of second driving circuit columns in the plurality of second driving circuit columns are coupled to second-color light-emitting elements, and a second part of second driving circuit columns in the plurality of second driving circuit columns are coupled to third-color light-emitting elements; and
the first light-emitting element column comprises a plurality of first-color light-emitting elements arranged in the first direction, and the second light-emitting element column comprises the second-color light-emitting elements and the third-color light-emitting elements arranged alternately in the first direction.

4. The display substrate according to claim 2, wherein one of the first light-emitting element row and the second light-emitting element row comprises a plurality of first-color light-emitting elements arranged in the second direction, and the other of the first light-emitting element row and the second light-emitting element row comprises the second-color light-emitting elements and the third-color light-emitting elements arranged alternately in the second direction.

5. The display substrate according to claim 1, wherein the light-emitting element comprises an anode pattern, the anode pattern comprises an anode body and an anode extension member coupled to each other, the subpixel further comprises a conductive connection structure, and the subpixel driving circuit is coupled to the anode extension member via the conductive connection structure,
wherein the conductive connection structure comprises at least two conductive connection members, the at least two conductive connection members are laminated one on another in a direction away from the base substrate, the subpixel driving circuit comprises a driving transistor and a light-emission control transistor, a first electrode of the light-emission control transistor is coupled to a second electrode of the driving transistor, and a second electrode of the light-emission control transistor is coupled to the anode extension member via the at least two conductive connection members,
wherein the conductive connection structure comprises a first conductive connection member, a second conductive connection member and a third conductive connection member laminated one on another in a direction away from the base substrate, the second conductive connection member is coupled to the first conductive connection member and the third conductive connection member, the first conductive connection member is coupled to the second electrode of the light-emission control transistor, and the third conductive connection member is coupled to the anode extension member; and
an orthogonal projection of the first conductive connection member onto the base substrate does not overlap with an orthogonal projection of the third conductive connection member onto the base substrate.

6.-7. (canceled)

8. The display substrate according to claim 5, further comprising a first source/drain metal layer, a second source/drain metal layer and a third source/drain metal layer laminated one on another in a direction away from the base substrate, wherein the first conductive connection member is arranged at a same layer, and made of a same material, as the first source/drain metal layer, the second conductive connection member is arranged at a same layer, and made of a same material, as the second source/drain metal layer, and the third conductive connection member is arranged at a same layer, and made of a same material, as the third source/drain metal layer.

9. The display substrate according to claim 5, wherein the plurality of driving circuit columns comprises a plurality of driving circuit groups arranged in the second direction, the driving circuit group comprises a first driving circuit column and a second driving circuit column proximate to each other, the driving circuit group comprises first driving units and second driving units arranged alternately in the first direction, the first driving unit comprises a first subpixel driving circuit and a second subpixel driving circuit arranged sequentially in the second direction, and the second driving unit comprises a third subpixel driving circuit and a fourth subpixel driving circuit arranged sequentially in the second direction;
the first subpixel driving circuit is coupled to a first anode extension member via a first conductive connection structure, the second subpixel driving circuit is coupled to a second anode extension member via a second conductive connection structure, the third subpixel driving circuit is coupled to a third anode extension member via a third conductive connection structure, and the fourth subpixel driving circuit is coupled to a fourth anode extension member via a fourth conductive connection structure; and
an orthogonal projection of the first anode extension member onto the base substrate does not overlap with an orthogonal projection of the second conductive connection structure onto the base substrate, and/or an orthogonal projection of the third anode extension member onto the base substrate does not overlap with an orthogonal projection of the fourth conductive connection structure onto the base substrate.

10. The display substrate according to claim 9, wherein the orthogonal projection of the first anode extension member onto the base substrate does not overlap with the orthogonal projection of the first conductive connection member in the first conductive connection structure onto the base substrate, and/or the orthogonal projection of the first anode extension member onto the base substrate does not overlap with an orthogonal projection of the second conductive connection member in the first conductive connection structure onto the base substrate.

11. The display substrate according to claim 9, wherein the orthogonal projection of the third anode extension member onto the base substrate does not overlap with the orthogonal projection of the first conductive connection member in the third conductive connection structure onto the base substrate, and/or the orthogonal projection of the third anode extension member onto the base substrate does not overlap with an orthogonal projection of the second conductive connection member in the third conductive connection structure onto the base substrate.

12. The display substrate according to claim 9, wherein an orthogonal projection of the second anode extension member onto the base substrate at least partially overlaps with an orthogonal projection of the first conductive connection structure onto the base substrate.

13. The display substrate according to claim 12, wherein the orthogonal projection of the second anode extension member onto the base substrate at least partially overlaps with the orthogonal projection of the second conductive connection member in the first conductive connection structure onto the base substrate, and/or the orthogonal projection of the second anode extension member onto the base substrate at least partially overlaps with the orthogonal projection of the third conductive connection member in the first conductive connection structure onto the base substrate.

14. The display substrate according to claim 12, wherein the orthogonal projection of the second anode extension member onto the base substrate does not overlap with the orthogonal projection the first conductive connection member in the second conductive connection structure onto the base substrate, and/or the orthogonal projection of the second anode extension member onto the base substrate at least partially overlaps with the orthogonal projection the second conductive connection member in the second conductive connection structure onto the base substrate.

15. The display substrate according to claim 12, wherein the second conductive connection member in the first conductive connection structure is arranged symmetrical with the second conductive connection member in the second conductive connection structure, and/or the second conductive connection member in the third conductive connection structure is arranged symmetrical with the second conductive connection member in the fourth conductive connection structure.

16. The display substrate according to claim 9, wherein an orthogonal projection of the second anode extension member onto the base substrate does not overlap with an orthogonal projection of the first conductive connection structure onto the base substrate,
wherein an orthogonal projection of a second anode body coupled to the second anode extension member onto the base substrate at least partially overlaps with the orthogonal projection of the first conductive connection member in an adjacent second conductive connection structure onto the base substrate, and/or the orthogonal projection of the second anode body coupled to the second anode extension member onto the base substrate at least partially overlaps with the orthogonal projection of the second conductive connection member in the adjacent second conductive connection structure onto the base substrate, wherein the adjacent second conductive connection structure and the second conductive connection structure coupled to the second anode extension member are arranged in the second direction; and/or
the orthogonal projection of the third conductive connection member in the second conductive connection structure onto the base substrate at least partially overlaps with the orthogonal projection of the second conductive connection member in the first conductive connection structure onto the base substrate; and/or the orthogonal projection of the second conductive connection member in the second conductive connection structure onto the base substrate does not overlap with the orthogonal projection of the third conductive connection member in the first conductive connection structure onto the base substrate; and/or
wherein at least a portion of the third conductive connection member in the first conductive connection structure extends in the first direction, at least a portion of the second conductive connection member in the second conductive connection structure extends in the second direction, and the orthogonal projection of the third conductive connection member in the first conductive connection structure onto the base substrate and the orthogonal projection of the second conductive connection member in the second conductive connection structure onto the base substrate are arranged in the first direction; and/or
wherein at least a portion of the third conductive connection member in the first conductive connection structure extends in a third direction, the third direction intersects the first direction and the second direction, and one end of the third conductive connection member in the first conductive connection structure is at least partially surrounded by the third conductive connection member in the second conductive connection structure.

17.-20. (canceled)

21. The display substrate according to claim 9, wherein an orthogonal projection of the fourth anode extension member onto the base substrate does not overlap with the orthogonal projection of the third conductive connection structure onto the base substrate.

22. The display substrate according to claim 21, wherein the orthogonal projection of the fourth anode extension member onto the base substrate does not overlap with the orthogonal projection of the first conductive connection member in the fourth conductive connection structure onto the base substrate, and/or the orthogonal projection of the fourth anode extension member onto the base substrate does not overlap with the orthogonal projection of the second conductive connection member in the fourth conductive connection structure onto the base substrate.

23. The display substrate according to claim 21, wherein the fourth anode extension member comprises at least a portion extending in the second direction, the second conductive connection member in the fourth conductive connection structure comprises at least a portion extending in the second direction, and the orthogonal projection of the fourth anode extension member onto the base substrate and the orthogonal projection of the second conductive connection member in the fourth conductive connection structure onto the base substrate are arranged in the first direction.

24. The display substrate according to claim 9, wherein the second conductive connection member in the first conductive connection structure and the second conductive connection member in the third conductive connection structure extend in a same direction;
the second conductive connection member in the second conductive connection structure and the second conductive connection member in the fourth conductive connection structure extend in a same direction; and
in the first conductive connection structure, the second conductive connection member has a first extension direction from the first conductive connection member to the third conductive connection member, in the second conductive connection structure, the second conductive connection member has a second extension direction from the first conductive connection member to the third conductive connection member, and the second extension direction is at least partially opposite to the first extension direction.

25. A display substrate, comprising a base substrate, and a plurality of subpixels and a plurality of data lines arranged on the base substrate, each of the subpixels comprising a subpixel driving circuit and a light-emitting element coupled to each other, wherein
a plurality of subpixel driving circuits comprised in the plurality of subpixels comprises a plurality of driving circuit columns, each of the driving circuit columns comprises a plurality of subpixel driving circuits arranged in a first direction, light-emitting elements coupled to the subpixel driving circuits in a same driving circuit column emit light in a same color, and each of the data lines is coupled to the subpixel driving circuits in a corresponding driving circuit column;
the plurality of driving circuit columns comprises a plurality of first driving circuit columns and a plurality of second driving circuit columns, the plurality of first driving circuit columns and the plurality of second driving circuit columns are arranged alternately in a second direction, and the second direction intersects the first direction;
the light-emitting elements coupled to the first driving circuit column are arranged in the first direction to form a first light-emitting element column, and the light-emitting elements coupled to the second diving circuit column are arranged in the first direction to form a second light-emitting element column; and
a driving transistor in the subpixel driving circuit comprises an active pattern, the light-emitting element comprises an anode pattern, the anode pattern comprises an anode body and an anode extension member coupled to each other, and in a same light-emitting element column, an orthogonal projection of the anode body onto the base substrate does not overlap with an orthogonal projection of the active pattern of the driving transistor in the subpixel driving circuit coupled to the anode body onto the base substrate,
wherein an orthogonal projection of the first light-emitting element column onto the base substrate at least partially overlaps with an orthogonal projection of the second driving circuit column onto the base substrate, and an orthogonal projection of the second light-emitting element column onto the base substrate at least partially overlaps with an orthogonal projection of the first driving circuit column onto the base substrate.

26. (canceled)

27. A display device, comprising the display substrate according to claim 1.
